(19) United States
(12) Patent Application Publication
(10) Pub. No.: US 2026/0152842 A1
(43) Pub. Date: Jun. 4, 2026

(54) DEPOSITION MASK, METHOD OF MANUFACTURING THE SAME, AND ELECTRONIC DEVICE MANUFACTURED BY USING THE SAME

(71) Applicant: Samsung Display Co., LTD., Yongin-si (KR)

(72) Inventor: Sung Woon KIM, Yongin-si (KR)

(21) Appl. No.: 19/282,338

(22) Filed: Jul. 28, 2025

(30) Foreign Application Priority Data
Dec. 3, 2024 (KR) 10-2024-0177525

(51) Int. Cl. C23C 14/04; H10K 71/16

(52) U.S. Cl. CPC C23C 14/042; H10K 71/166

(57) ABSTRACT

A deposition mask includes a mask substrate and a membrane disposed on the mask substrate. An upper opening is defined in a front surface portion of the mask substrate and a cell opening is defined in a rear surface portion of the mask substrate and connected to the upper opening. The membrane includes a mask cell region disposed in the upper opening and provided with a plurality of pixel openings defined therethrough, and a grid region disposed on a front surface of the mask substrate.

### BACKGROUND

This application claims priority to Korean Patent Application No. 10-2024-0177525, filed on Dec. 3, 2024, and all the benefits accruing therefrom under 35 U.S.C. § 119, the content of which in its entirety is herein incorporated by reference.

### 1. Field

The present disclosure relates to a deposition mask, a method of manufacturing the deposition mask, and an electronic device manufactured by using the deposition mask.

### 2. Description of the Related Art

Wearable devices in which a focus is formed at a distance close to user's eyes have been developed in the form of glasses or a helmet. For example, the wearable device may be a head mounted display (HMD) device or AR glasses. The wearable device may provide an augmented reality (AR) screen or a virtual reality (VR) screen to a user.

In the case of wearable devices such as the HMD device or the AR glasses, a display specification of approximately 3000 pixels per inch (PPI) or higher is desired to allow users to use them for a long time without symptoms of dizziness. To this end, organic light emitting diode on silicon (OLEDoS) technology is emerging for use in a high-resolution small organic light emitting display device. The OLEDoS is a technology in which organic light emitting diodes (OLED) are arranged on a semiconductor substrate on which complementary metal oxide semiconductor (CMOS) elements are arranged.

In order to manufacture a display panel with a high resolution of about 3000 PPI or higher, a high-resolution deposition mask is typically used. For example, the deposition mask may be manufactured by forming a membrane having a plurality of pixel openings on a mask substrate such as a silicon wafer, and partially removing the mask substrate to form cell openings that expose the pixel openings.

### SUMMARY

In a deposition process to form light emitting layers of a display panel, a backplane substrate may be positioned on a deposition mask, and a vapor deposition material provided from a deposition source may be deposited on the backplane substrate through pixel openings of the deposition mask. When a backplane substrate is positioned on the deposition mask as described above, the membrane of the deposition mask may be damaged by contact with the backplane substrate. Additionally, when particles exist between the backplane substrate and the deposition mask, the membrane of the deposition mask may be damaged by the particles.

Embodiments of the present disclosure provide an improved deposition mask capable of effectively preventing or substantially reducing damage to a membrane, a method of manufacturing the deposition mask, and an electronic device manufactured by using the deposition mask.

However, embodiments of the present disclosure are not limited to those set forth herein. The above and other embodiments of the present disclosure will become more apparent to one of ordinary skill in the art to which the present disclosure pertains by referencing the detailed description of the present disclosure given below.

In accordance with an embodiment of the present disclosure, a deposition mask includes a mask substrate and a membrane disposed on the mask substrate. In such an embodiment, an upper opening is defined in a front surface portion of the mask substrate and a cell opening is defined in a rear surface portion of the mask substrate and connected to the upper opening, and the membrane includes a mask cell region disposed in the upper opening and provided with a plurality of pixel openings defined therethrough, and a grid region disposed on a front surface of the mask substrate.

In accordance with some embodiments of the present disclosure, the deposition mask may further include an intermediate inorganic film disposed between the mask substrate and the membrane, and the intermediate inorganic film may be provided with an intermediate opening connecting the mask cell region and the cell opening to each other in a way such that the mask cell region is exposed through the cell opening.

In accordance with some embodiments of the present disclosure, inner side surfaces of the mask substrate defining the cell opening may be directly connected to inner side surfaces of the mask substrate defining the upper opening.

In accordance with some embodiments of the present disclosure, the intermediate opening may have a width equal to a width of the upper opening.

In accordance with some embodiments of the present disclosure, the upper opening may be a recessed opening connected to the cell opening.

In accordance with some embodiments of the present disclosure, the deposition mask may further include an intermediate inorganic film disposed between the mask substrate and the membrane, and the intermediate inorganic film may be provided with an intermediate opening defined between the mask cell region and the cell opening in a way such that the pixel openings communicate with the cell opening.

In accordance with some embodiments of the present disclosure, the intermediate opening may have a width greater than a width of the cell opening.

In accordance with some embodiments of the present disclosure, the cell opening may have a first width adjacent to the front surface of the mask substrate and a second width adjacent to a rear surface of the mask substrate, and the intermediate opening may have a width greater than the first width of the cell opening.

In accordance with some embodiments of the present disclosure, the mask substrate may include a ring-shaped stepped portion surrounding the cell opening, the upper opening may be defined by the ring-shaped stepped portion, the intermediate inorganic film may includes a ring-shaped inorganic pattern disposed on the ring-shaped stepped portion and surrounding the intermediate opening, and the mask cell region may be supported by the ring-shaped inorganic pattern and the ring-shaped stepped portion.

In accordance with another embodiment of the present disclosure, a method of manufacturing a deposition mask includes forming a recess in a front surface portion of a mask substrate, forming a membrane on a front surface of the mask substrate and inner surfaces of the mask substrate defining the recess, forming a plurality of pixel openings through a portion of the membrane formed on a bottom surface of the recess, and forming a cell opening through the mask substrate to be connected to the pixel openings.

In accordance with some embodiments of the present disclosure, the method may further include forming an intermediate inorganic film on the front surface of the mask substrate and the inner surfaces of the mask substrate defining the recess, the membrane may be formed on the intermediate inorganic film, and the pixel openings may be formed in a way such that portions of the intermediate inorganic film formed on the bottom surface of the mask substrate defining the recess are removed.

In accordance with some embodiments of the present disclosure, the method may further include forming an intermediate opening connecting the pixel openings and the cell opening by partially removing the intermediate inorganic film.

In accordance with some embodiments of the present disclosure, the cell opening may be formed in a way such that inner side surfaces of the mask substrate defining the recess are directly connected to inner side surfaces of the mask substrate defining the cell opening.

In accordance with some embodiments of the present disclosure, the intermediate opening may be formed to have a width equal to a width of the recess.

In accordance with some embodiments of the present disclosure, the cell opening may be formed in a way such that the bottom surface of the mask substrate defining the recess is partially removed.

In accordance with some embodiments of the present disclosure, the method may further include forming an intermediate inorganic film on the front surface of the mask substrate and the inner surfaces of the mask substrate defining the recess, the membrane is formed on the intermediate inorganic film, and a portion of the intermediate inorganic film formed on the bottom surface of the recess may be partially exposed by the cell opening.

In accordance with some embodiments of the present disclosure, the method may further include removing a portion of the intermediate inorganic film exposed by the cell opening to form an intermediate opening connecting the pixel openings and the cell opening to each other.

In accordance with some embodiments of the present disclosure, the intermediate opening may be formed to have a width less than a width of the recess.

In accordance with some embodiments of the present disclosure, while the forming the cell opening, a ring-shaped stepped portion surrounding the cell opening may be formed, and while the forming the intermediate opening, a ring-shaped inorganic pattern surrounding the intermediate opening may be formed on the ring-shaped stepped portion.

In accordance with still another embodiment of the present disclosure, an electronic device includes a display panel. In such an embodiment, the display panel includes a backplane substrate and a plurality of light emitting layers formed on the backplane substrate using a deposition mask. In such an embodiment, the deposition mask includes a mask substrate and a membrane disposed on the mask substrate. In such an embodiment, an upper opening is defined in a front surface portion of the mask substrate and a cell opening is defined in a rear surface portion of the mask substrate and connected to the upper opening. In such an embodiment, the membrane includes a mask cell region disposed in the upper opening and provided with a plurality of pixel openings defined therethrough, and a grid region disposed on a front surface of the mask substrate.

In accordance with some embodiments of the present disclosure, the electronic device may further include at least one selected from a processor, a memory, and a power module.

According to embodiments of the present disclosure as described above, the deposition mask may include a mask substrate and a membrane disposed on the mask substrate. In such embodiments, the mask substrate may be provided with an upper opening corresponding to a recess formed in a front surface portion and a cell opening connected to the recess. The membrane may include a mask cell region disposed in the recess and provided with a plurality of pixel openings, and a grid region disposed on a front surface of the mask substrate. Accordingly, in a deposition process by using the deposition mask, the mask cell region may be positioned lower than the grid region. As a result, the mask cell region may be spaced apart from the backplane substrate while the deposition process is performed, and thus, damage to the mask cell region may be prevented or reduced.

Other features and embodiments may be apparent from the following detailed description and the drawings.

### BRIEF DESCRIPTION OF THE DRAWINGS

The above and other features of the present disclosure will become more apparent by describing in detail embodiments thereof with reference to the accompanying drawings, in which:

FIG. 1 is a block diagram of an electronic device according to an embodiment of the present disclosure;

FIG. 2 is a schematic diagram of an electronic device according to various embodiments of the present disclosure;

FIG. 3 is an exploded perspective view illustrating a display device according to an embodiment of the present disclosure;

FIG. 4 is a block diagram illustrating the display device shown in FIG. 3;

FIG. 5 is an equivalent circuit diagram illustrating an example of a first sub-pixel shown in FIG. 4;

FIG. 6 is a schematic plan view illustrating an example of a display panel shown in FIG. 3;

FIG. 7 is a schematic enlarged plan view illustrating an example of a display area shown in FIG. 6;

FIG. 8 is a schematic enlarged plan view illustrating another example of the display area shown in FIG. 6;

FIG. 9 is a schematic cross-sectional view illustrating an example of the display panel taken along line I1-I1′ shown in FIG. 7;

FIG. 10 is a schematic cross-sectional view illustrating another example of the display panel taken along line I1-I1′ shown in FIG. 7;

FIG. 11 is a schematic perspective view illustrating an example of a head mounted display;

FIG. 12 is a schematic exploded perspective view illustrating the head mounted display shown in FIG. 11;

FIG. 13 is a schematic perspective view illustrating another example of the head mounted display;

FIG. 14 is a schematic diagram illustrating a deposition mask and a deposition apparatus including the deposition mask according to an embodiment of the present disclosure;

FIG. 15 is a schematic bottom view illustrating a backplane substrate shown in FIG. 14;

FIG. 16 is a schematic plan view illustrating the deposition mask shown in FIG. 14;

FIG. 17 is a schematic plan view illustrating mask cell regions shown in FIG. 16;

FIG. 18 is a schematic cross-sectional view taken along line I2-I2′ shown in FIG. 17;

FIG. 19 is an enlarged cross-sectional view schematically illustrating mask cell region, intermediate opening, and cell opening shown in FIG. 18;

FIG. 20 is a schematic cross-sectional view illustrating a deposition mask according to another embodiment of the present disclosure;

FIG. 21 is a schematic enlarged cross-sectional view illustrating mask cell region, intermediate opening, and cell opening shown in FIG. 20;

FIGS. 22 to 28 are schematic cross-sectional views illustrating a method of manufacturing a deposition mask according to an embodiment of the present disclosure; and

FIGS. 29 to 31 are schematic cross-sectional views illustrating a method of manufacturing a deposition mask according to another embodiment of the present disclosure.

### DETAILED DESCRIPTION

The invention will now be described more fully hereinafter with reference to the accompanying drawings, in which various embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art.

It will also be understood that when an element or a layer is referred to as being “on” another element or layer, it can be directly on the other element or layer, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the invention. Similarly, the second element could also be termed the first element.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Features of each of various embodiments of the disclosure may be partially or entirely combined with each other and may technically variously interwork with each other, and respective embodiments may be implemented independently of each other or may be implemented together in association with each other.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments will be described in detail with reference to the accompanying drawings.

The display device according to an embodiment of the present disclosure can be applied to various electronic devices. The electronic device according to the an embodiment of the present disclosure includes the display device described above, and may further include modules or devices having additional functions in addition to the display device.

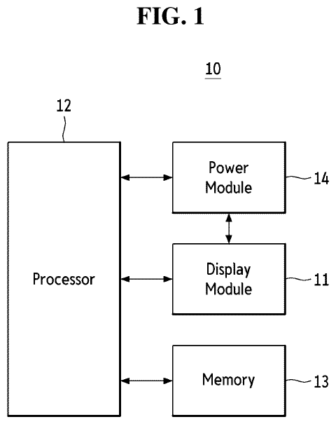

FIG. 1 is a block diagram of an electronic device according to an embodiment of the present disclosure.

Referring to FIG. 1, the electronic device 10 according to an embodiment of the present disclosure may include a display module 11, a processor 12, a memory 13, and a power module 14.

The processor 12 may include at least one selected from a central processing unit (CPU), an application processor (AP), a graphic processing unit (GPU), a communication processor (CP), an image signal processor (ISP), and a controller.

The memory 13 may store data information used for the operation of the processor 12 or the display module 11. When the processor 12 executes an application stored in the memory 13, an image data signal and/or an input control signal is transmitted to the display module 11, and the display module 11 can process the received signal and output image information through a display screen.

The power module 14 may include a power supply module such as, for example a power adapter or a battery, and a power conversion module that converts the power supplied by the power supply module to generate power necessary for the operation of the electronic device 10.

At least one of the components of the electronic device 10 according to an embodiment of the present disclosure may be included in the display device 20 according to the embodiments of the present disclosure. In addition, some modules of the individual modules functionally included in one module may be included in the display device 20, and other modules may be provided separately from the display device 10. In an embodiment, for example, the display device 20 may include the display module 11, and the processor 12, the memory 13, and the power module 14 may be provided in the form of other devices within the electronic device 10 other than the display device 20.

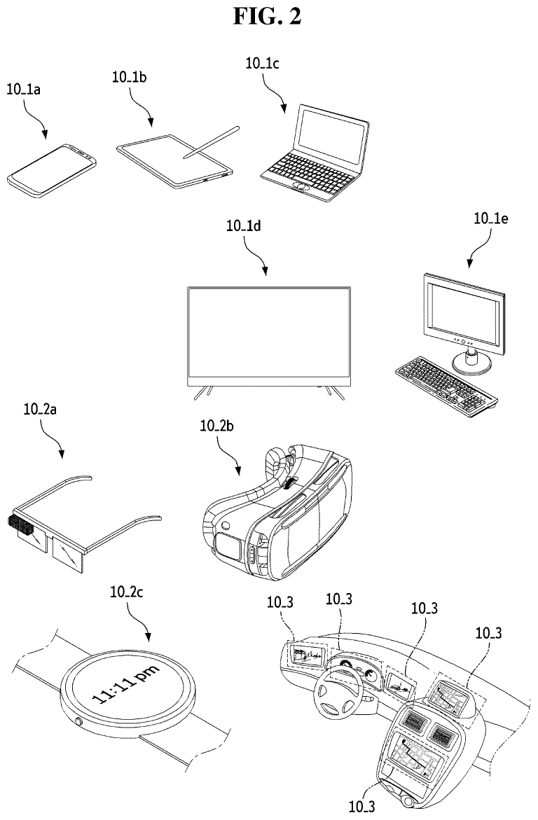

FIG. 2 is a schematic diagram of an electronic device according to various embodiments of the present disclosure.

Referring to FIG. 2, various electronic devices to which display devices 20 according to embodiments of the present disclosure are applied may include not only image display electronic devices such as a smart phone 10_1a, a tablet personal computer (PC) 10_1b, a laptop 10_1c, a television (TV) 10_1d, and a desk monitor 10_1e, but also wearable electronic devices including display modules such as, for example smart glasses 10_2a, a head mounted display 10_2b, and a smart watch 10_2c, and vehicle electronic devices 10_3 including display modules such as a center information display (CID) and a room mirror display arranged on a dashboard, center fascia, and dashboard of an automobile.

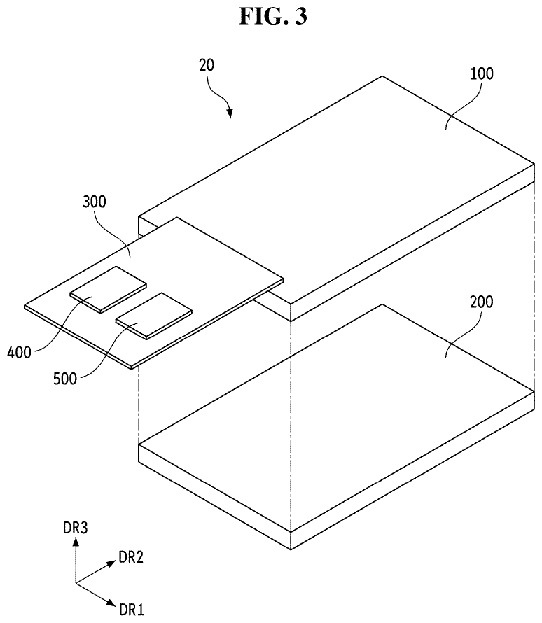

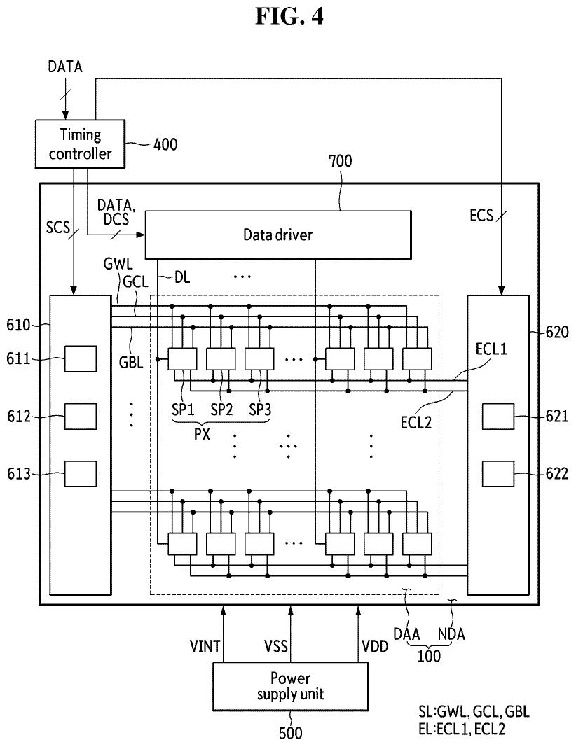

FIG. 3 is an exploded perspective view illustrating a display device according to an embodiment of the present disclosure. FIG. 4 is a block diagram illustrating the display device shown in FIG. 3.

Referring to FIGS. 3 and 4, a display device 20 according to an embodiment may be a device displaying a moving image or a still image. A display device 20 according to an embodiment may be used as the electronic device 10 or the display module 11 of the electronic device 10. For example, the display device 20 according to an embodiment may be applied to portable electronic devices 10 such as a mobile phone, a smartphone, a tablet personal computer, a mobile communication terminal, an electronic organizer, an electronic book, a portable multimedia player (PMP), a navigation system, an ultra mobile PC (UMPC), and the like. The display device 20 according to an embodiment may be applied as a display module 11 of electronic devices 10 such as a television, a laptop, a monitor, a billboard, or an Internet-of-Things (IoT) terminal, and the like. The display device 20 according to an embodiment may be applied to electronic devices 10 such as a smart watch, a watch phone, a head mounted display (HMD) for implementing virtual reality and augmented reality, and the like.

The display device 20 according to an embodiment may include a display panel 100, a heat dissipation layer 200, a circuit board 300, a timing control circuit 400, and a power supply circuit 500.

The display panel 100 may have a planar shape similar to a quadrilateral shape. For example, the display panel 100 may have a planar shape similar to a quadrilateral shape, having a short side of a first direction DR1 and a long side of a second direction DR2 intersecting the first direction DR1. Here, the planar shape may be a shape when viewed in a plan view or viewed in a third direction DR3. Here, the third direction DR3 may be a thickness direction of the display panel 100. In the display panel 100, a corner where a short side in the first direction DR1 and a long side in the second direction DR2 meet may be right-angled or rounded with a predetermined curvature. The planar shape of the display panel 100 is not limited to a quadrilateral shape, and may be a shape similar to another polygonal shape, a circular shape, or an elliptical shape. The planar shape of the display device 20 may conform to the planar shape of the display panel 100, but the present disclosure is not limited thereto.

In an embodiment, the display panel 100 may include a plurality of pixels PX, a plurality of scan lines SL, a plurality of emission control lines EL, a plurality of data lines DL, a scan driver 610, an emission driver 620, and a data driver 700. The display panel 100 may be divided into a display area DAA displaying an image and a non-display area NDA in which no image is displayed as shown in FIG. 4.

The plurality of pixels PX may be disposed in the display area DAA. The plurality of pixels PX may be arranged in a matrix form along the first direction DR1 and the second direction DR2. The plurality of scan lines SL and the plurality of emission control lines EL may extend in the first direction DR1, while being arranged in the second direction DR2. The plurality of data lines DL may extend in the second direction DR2, while being arranged in the first direction DR1.

The plurality of scan lines SL may include a plurality of write scan lines GWL, a plurality of control scan lines GCL, and a plurality of bias scan lines GBL. The plurality of emission control lines EL include a plurality of first emission control lines ECL1 and a plurality of second emission control lines ECL2.

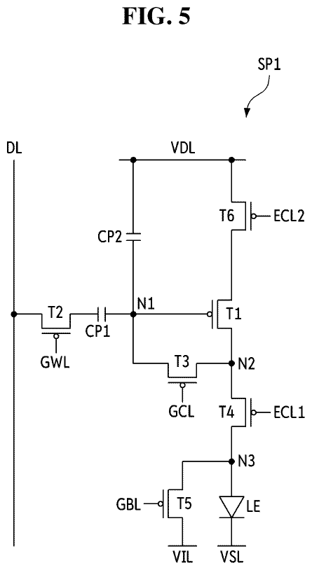

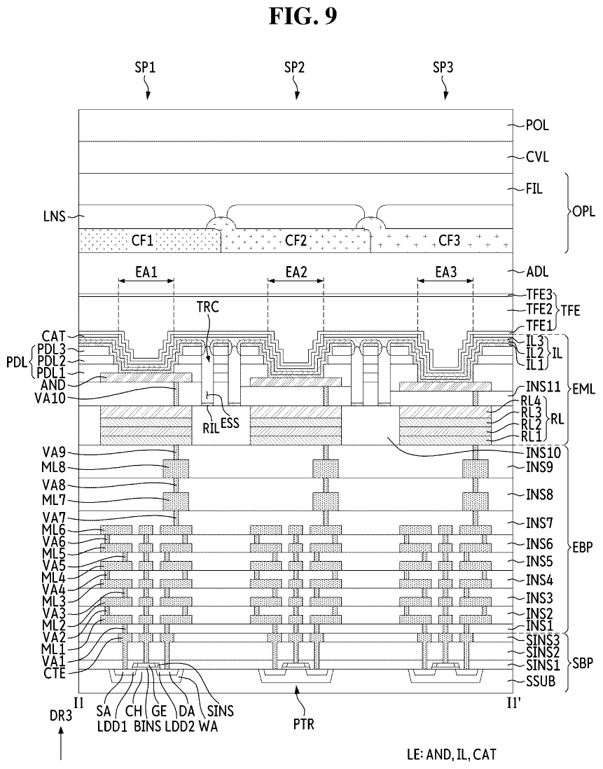

The plurality of pixels PX may include a plurality of sub-pixels SP1, SP2, and SP3. The plurality of sub-pixels SP1, SP2, and SP3 may include a plurality of pixel transistors as shown in FIG. 5, and the plurality of pixel transistors may be formed by a semiconductor process and disposed on a semiconductor substrate SSUB (see FIG. 9). In an embodiment, for example, the plurality of pixel transistors of the data driver 700 may include or be formed of complementary metal oxide semiconductor (CMOS), but the present disclosure is not limited thereto.

Each of the plurality of sub-pixels SP1, SP2, and SP3 may be connected to one write scan line GWL, one control scan line GCL, one bias scan line GBL, one first emission control line ECL1, one second emission control line ECL2, and one data line DL. Each of the plurality of sub-pixels SP1, SP2, and SP3 may receive a data voltage of the data line DL in response to a write scan signal of the write scan line GWL, and emit light from the light emitting element according to the data voltage.

The scan driver 610, the emission driver 620, and the data driver 700 may be disposed in the non-display area NDA.

The scan driver 610 includes a plurality of scan transistors, and the emission driver 620 includes a plurality of light emitting transistors. The plurality of scan transistors and the plurality of light emitting transistors may be formed on the semiconductor substrate SSUB (see FIG. 9) through a semiconductor process. In an embodiment, for example, the plurality of scan transistors and the plurality of light emitting transistors may include or be formed of CMOS, but the present disclosure is not limited thereto.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing control circuit 400. The write scan signal output unit 611 may generate write scan signals based on the scan timing control signal SCS of the timing control circuit 400 and output them sequentially to the write scan lines GWL. The control scan signal output unit 612 may generate control scan signals in response to the scan timing control signal SCS and sequentially output them to the control scan lines GCL. The bias scan signal output unit 613 may generate bias scan signals according to the scan timing control signal SCS and output them sequentially to the bias scan lines GBL.

The emission driver 620 includes a first emission control driver 621 and a second emission control driver 622. Each of the first emission control driver 621 and the second emission control driver 622 may receive an emission timing control signal ECS from the timing control circuit 400. The first emission control driver 621 may generate first emission control signals based on the emission timing control signal ECS and sequentially output them to the first emission control lines ECL1. The second emission control driver 622 may generate second emission control signals based on the emission timing control signal ECS and sequentially output them to the second emission control lines ECL2.

The data driver 700 may include a plurality of data transistors, and the plurality of data transistors may be formed on the semiconductor substrate SSUB (see FIG. 9) through a semiconductor process. In an embodiment, for example, the plurality of data transistors may be formed of CMOS, but the present disclosure is not limited thereto.

The data driver 700 may receive digital video data DATA and a data timing control signal DCS from the timing control circuit 400. The data driver 700 converts the digital video data DATA into analog data voltages based on the data timing control signal DCS and outputs the analog data voltages to the data lines DL. In this case, the sub-pixels SP1, SP2, and SP3 may be selected by the write scan signal of the scan driver 610, and data voltages may be supplied to the selected sub-pixels SP1, SP2, and SP3.

The heat dissipation layer 200 may overlap the display panel 100 in a third direction DR3, which is a thickness direction of the display panel 100. The heat dissipation layer 200 may be disposed on one surface of the display panel 100, for example, on the rear surface thereof. The heat dissipation layer 200 serves to dissipate heat generated from the display panel 100. The heat dissipation layer 200 may include a metal layer having high thermal conductivity, such as graphite, silver (Ag), copper (Cu), or aluminum (Al).

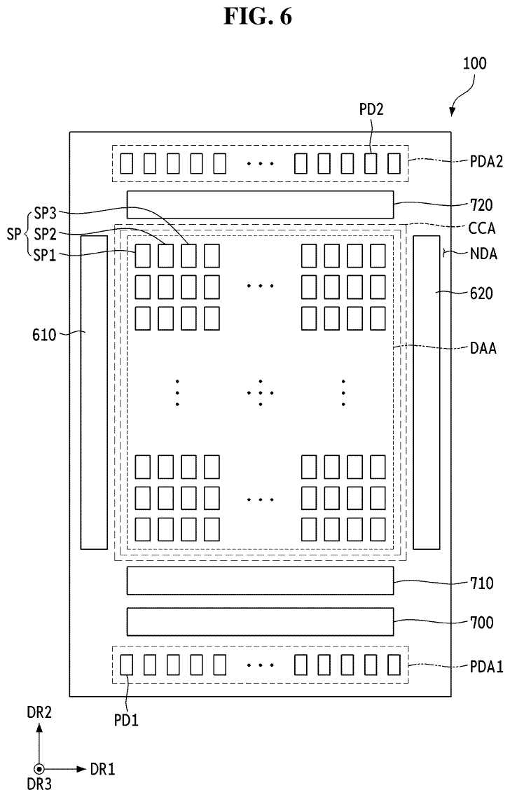

The circuit board 300 may be electrically connected to a plurality of first pads PD1 (see FIG. 6) of a first pad portion PDA1 (see FIG. 6) of the display panel 100 by using a conductive adhesive member such as an anisotropic conductive film. The circuit board 300 may be a flexible printed circuit board with a flexible material, or a flexible film. Although the circuit board 300 is illustrated in FIG. 3 as being unfolded, the circuit board 300 may be bent. When the circuit board 300 is in a bent state, one end of the circuit board 300 may be disposed on the rear surface of the display panel 100 and/or the rear surface of the heat dissipation layer 200. The other end of the circuit board 300 may be connected to the plurality of first pads PD1 (see FIG. 6) of the first pad portion PDA1 (see FIG. 6) of the display panel 100 by using a conductive adhesive member. One end of the circuit board 300 may be an opposite end of the other end of the circuit board 300.

The timing control circuit 400 may receive digital video data and timing signals inputted from the outside. The timing control circuit 400 may generate the scan timing control signal SCS, the emission timing control signal ECS, and the data timing control signal DCS for controlling the display panel 100 in response to the timing signals. The timing control circuit 400 may output the scan timing control signal SCS to the scan driver 610, and output the emission timing control signal ECS to the emission driver 620. The timing control circuit 400 may output the digital video data and the data timing control signal DCS to the data driver 700.

The power supply circuit 500 may generate a plurality of panel driving voltages according to a power voltage from the outside. In an embodiment, for example, the power supply circuit 500 may generate a first driving voltage VSS, a second driving voltage VDD, and a third driving voltage VINT and supply them to the display panel 100. The first driving voltage VSS, the second driving voltage VDD, and the third driving voltage VINT will be described later in conjunction with FIG. 5.

In an embodiment, each of the timing control circuit 400 and the power supply circuit 500 may be formed as or defined by an integrated circuit (IC) and attached to one surface of the circuit board 300. In such an embodiment, the scan timing control signal SCS, the emission timing control signal ECS, the digital video data DATA, and the data timing control signal DCS of the timing control circuit 400 may be supplied to the display panel 100 through the circuit board 300. Further, the first driving voltage VSS, the second driving voltage VDD, and the third driving voltage VINT of the power supply circuit 500 may be supplied to the display panel 100 through the circuit board 300.

Alternatively, each of the timing control circuit 400 and the power supply circuit 500 may be disposed in the non-display area NDA of the display panel 100, similarly to the scan driver 610, the emission driver 620, and the data driver 700. In such an embodiment, the timing control circuit 400 may include a plurality of timing transistors, and each power supply circuit 500 may include a plurality of power transistors. The plurality of timing transistors and the plurality of power transistors may be formed on the semiconductor substrate SSUB (see FIG. 9) through a semiconductor process. In an embodiment, for example, the plurality of timing transistors and the plurality of power transistors may include or be formed of CMOS, but the present disclosure is not limited thereto. Each of the timing control circuit 400 and the power supply circuit 500 may be disposed between the data driver 700 and the first pad portion PDA1 (see FIG. 6).

FIG. 5 is an equivalent circuit diagram illustrating an example of a first sub-pixel shown in FIG. 4.

Referring to FIG. 5, in an embodiment, the first sub-pixel SP1 may be connected to the write scan line GWL, the control scan line GCL, the bias scan line GBL, the first emission control line ECL1, the second emission control line ECL2, and the data line DL. Further, the first sub-pixel SP1 may be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied.

The first sub-pixel SP1 may include a plurality of transistors T1 to T6, a light emitting element LE, a first capacitor CP1, and a second capacitor CP2.

The light emitting element LE emits light in response to a driving current flowing through the channel of the first transistor T1. The emission amount of the light emitting element LE may be proportional to the driving current. The first electrode of the light emitting element LE may be an anode electrode, and the second electrode of the light emitting element LE may be a cathode electrode. The light emitting element LE may be an organic light emitting diode including a first electrode, a second electrode, and an organic light emitting layer disposed between the first electrode and the second electrode, but the present disclosure is not limited thereto. In an embodiment, for example, the light emitting element LE may be an inorganic light emitting element including a first electrode, a second electrode, and an inorganic semiconductor disposed between the first electrode and the second electrode, in which case the light emitting element LE may be a micro light emitting diode.

The first transistor T1 may be a driving transistor that controls a source-drain current (hereinafter referred to as “driving current”) flowing between the source electrode and the drain electrode thereof based on a voltage applied to the gate electrode thereof.

A second transistor T2 may be connected between one electrode of the first capacitor CP1 and the data line DL. The second transistor T2 is turned on by the write scan signal of the write scan line GWL to connect the one electrode of the first capacitor CP1 to the data line DL. Accordingly, the data voltage of the data line DL may be applied to the one electrode of the first capacitor CP1.

A third transistor T3 may be connected between the first node N1 and the second node N2. The third transistor T3 is turned on by the control scan signal of the control scan line GCL to connect the first node N1 to the second node N2. For this reason, when the gate electrode and the source electrode of the first transistor T1 are connected, the first transistor T1 may operate like a diode.

The fourth transistor T4 may be connected between the second node N2 and a third node N3. The fourth transistor T4 is turned on by the first emission control signal of the first emission control line ECL1 to connect the second node N2 to the third node N3. Accordingly, the driving current of the first transistor T1 may be supplied to the light emitting element LE. A fifth transistor T5 may be disposed between the third node N3 and the third driving voltage line VIL. The fifth transistor T5 is turned on by the bias scan signal of the bias scan line GBL to connect the third node N3 to the third driving voltage line VIL. Accordingly, the third driving voltage VINT of the third driving voltage line VIL may be applied to the first electrode of the light emitting element LE.

The sixth transistor T6 may be connected between the source electrode of the first transistor T1 and the second driving voltage line VDL. The sixth transistor T6 is turned on by the second emission control signal of the second emission control line ECL2 to connect the source electrode of the first transistor T1 to the second driving voltage line VDL. Accordingly, the second driving voltage VDD of the second driving voltage line VDL may be applied to the source electrode of the first transistor T1.

The first capacitor CP1 is connected or formed between the first node N1 and the drain electrode of the second transistor T2. The second capacitor CP2 is connected or formed between the gate electrode of the first transistor T1 and the second driving voltage line VDL.

Each of the first to sixth transistors T1 to T6 may be a metal-oxide-semiconductor field effect transistor (MOSFET). In an embodiment, for example, each of the first to sixth transistors T1 to T6 may be a P-type MOSFET, but the present disclosure is not limited thereto. Each of the first to sixth transistors T1 to T6 may be an N-type MOSFET. Alternatively, some of the first to sixth transistors T1 to T6 may be P-type MOSFETs, and each of the remaining transistors may be an N-type MOSFET.

Although FIG. 5 illustrates an embodiment where the first sub-pixel SP1 includes six transistors T1 to T6 and two capacitors C1 and C2, it should be noted that the equivalent circuit diagram of the first sub-pixel SP1 is not limited to that shown in FIG. 5. In an embodiment, for example, the number of transistors and the number of capacitors of the first sub-pixel SP1 are not limited to those shown in FIG. 5.

in an embodiment, the equivalent circuit diagram of the second sub-pixel SP2 and the equivalent circuit diagram of the third sub-pixel SP3 may be substantially the same as the equivalent circuit diagram of the first sub-pixel SP1 described in conjunction with FIG. 5. Therefore, any repetitive detailed description of the equivalent circuit diagram of the second sub-pixel SP2 and the equivalent circuit diagram of the third sub-pixel SP3 will be omitted.

FIG. 6 is a schematic plan view illustrating an example of a display panel shown in FIG. 3.

Referring to FIG. 6, the display area DAA of the display panel 100 according to an embodiment includes the plurality of pixels PX arranged in a matrix form. The non-display area NDA of the display panel 100 according to an embodiment includes the scan driver 610, the emission driver 620, the data driver 700, a first distribution circuit 710, a second distribution circuit 720, the first pad portion PDA1, and a second pad portion PDA2.

The scan driver 610 may be disposed on the first side of the display area DAA, and the emission driver 620 may be disposed on the second side of the display area DAA. In an embodiment, for example, the scan driver 610 may be disposed on one side of the display area DAA in the first direction DR1, and the emission driver 620 may be disposed on the other side of the display area DAA in the first direction DR1. However, the present disclosure is not limited thereto, and the scan driver 610 and the emission driver 620 may be disposed on both the first side and the second side of the display area DAA.

The first pad portion PDA1 may include the plurality of first pads PD1 connected to pads or bumps of the circuit board 300 through a conductive adhesive member. The first pad portion PDA1 may be disposed on the third side of the display area DAA. In an embodiment, for example, the first pad portion PDA1 may be disposed on one side of the display area DAA in the second direction DR2. The first pad portion PDA1 may be disposed outside the data driver 700 in the second direction DR2.

The second pad portion PDA2 may include a plurality of second pads PD2 corresponding to inspection pads that test whether the display panel 100 operates normally. The plurality of second pads PD2 may be connected to a jig or a probe pin during an inspection process, or may be connected to a circuit board for inspection. The circuit board for inspection may be a printed circuit board made of a rigid material or a flexible printed circuit board made of a flexible material.

The second pad portion PDA2 may be disposed on the fourth side of the display area DAA. In an embodiment, for example, the second pad portion PDA2 may be disposed on the other side of the display area DAA in the second direction DR2. The second pad portion PDA2 may be disposed outside the second distribution circuit 720 in the second direction DR2.

The first distribution circuit 710 distributes data voltages applied through the first pad portion PDA1 to the plurality of data lines DL. In an embodiment, for example, the first distribution circuit 710 may distribute the data voltages applied through one first pad PD1 of the first pad portion PDA1 to the P (P is a positive integer of 2 or more) data lines DL, and as a result, the number of the plurality of first pads PD1 may be reduced. The first distribution circuit 710 may be disposed on the third side of the display area DAA of the display panel 100. In an embodiment, for example, the first distribution circuit 710 may be disposed on one side of the display area DAA in the second direction DR2.

The second distribution circuit 720 distributes signals applied through the second pad portion PDA2 to the scan driver 610, the emission driver 620, and the data lines DL. The second pad portion PDA2 and the second distribution circuit 720 may be configured to inspect the operation of each of the pixels PX in the display area DAA. The second distribution circuit 720 may be disposed on the fourth side of the display area DAA of the display panel 100. For example, the second distribution circuit 720 may be disposed on the other side of the display area DAA in the second direction DR2.

A cathode connection part CCA may be a region where a second electrode CAT (see FIG. 9) of a display element layer EML (see FIG. 9) is connected to the first driving voltage line VSL of the non-display area NDA. The cathode connection part CCA may be disposed outside at least one side of the display area DAA. In an embodiment, for example, the cathode connection part CCA may be disposed outside at least on one side among the left side, the right side, the upper side, and the lower side of the display area DAA. Alternatively, the cathode connection part CCA may be disposed to surround the display area DAA as shown in FIG. 6 to minimize a deviation in the first driving voltage VSS caused by voltage drop (IR drop) or voltage rise (IR rising) of the second electrode CAT in the display area DAA.

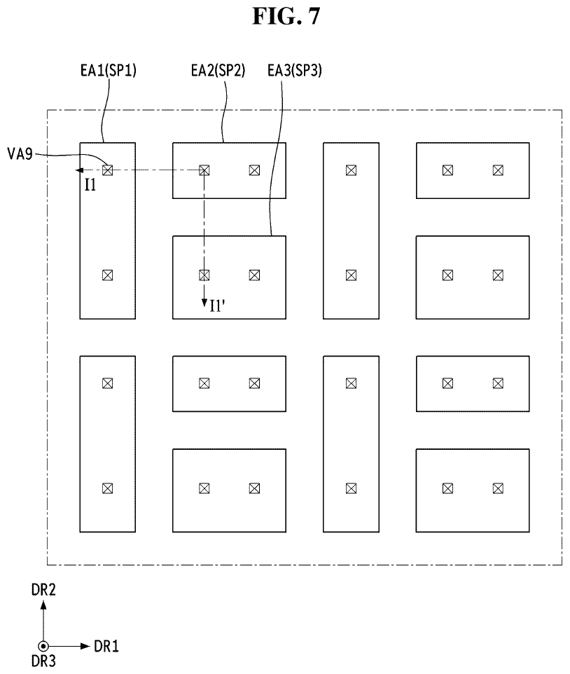

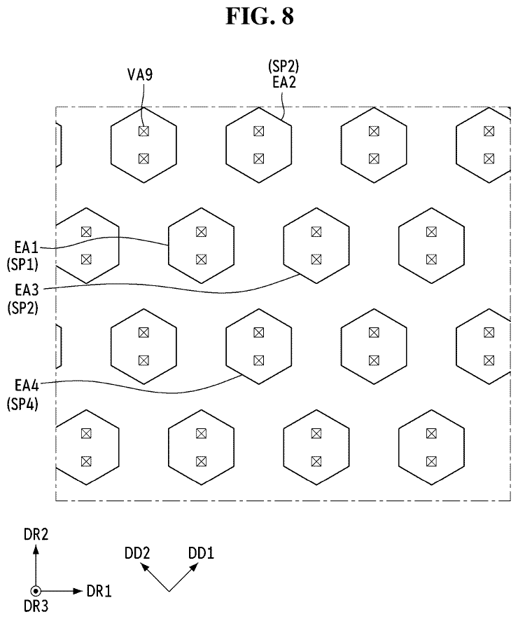

FIG. 7 is a schematic enlarged plan view illustrating an example of a display area shown in FIG. 6. FIG. 8 is a schematic enlarged plan view illustrating another example of the display area shown in FIG. 6.

Referring to FIGS. 7 and 8, in an embodiment, each of the pixels PX includes the first emission area EA1 that is an emission area of the first sub-pixel SP1, the second emission area EA2 that is an emission area of the second sub-pixel SP2, and the third emission area EA3 that is an emission area of the third sub-pixel SP3.

The first emission area EA1, the second emission area EA2, and the third emission area EA3 may have, in plan view, a quadrilateral or hexagonal shape as shown in FIGS. 7 and 8, but the present disclosure is not limited thereto. The first emission area EA1, the second emission area EA2, and the third emission area EA3 may have a polygonal shape other than a quadrangle or hexagon, a circular shape, an elliptical shape, or an atypical shape in plan view.

In an embodiment, as shown in FIG. 7, in each of the plurality of pixels PX, the first emission area EA1 and the second emission area EA2 may be adjacent to each other in the first direction DR1. Further, the first emission area EA1 and the third emission area EA3 may be adjacent to each other in the first direction DR1. In addition, the second emission area EA2 and the third emission area EA3 may be adjacent to each other in the second direction DR2. The area of the first emission area EA1, the area of the second emission area EA2, and the area of the third emission area EA3 may be different.

Alternatively, as shown in FIG. 8, the emission areas EA1, EA2, EA3, and EA4 may have a hexagonal shape in plan view. In such an embodiment, the first emission area EA1 and the third emission area EA3 may be adjacent in the first direction DR1, and the second emission area EA2 and the fourth emission area EA4 may be adjacent in the second direction DR2. Additionally, the first emission area EA1 and the second emission area EA2 may be adjacent in a first diagonal direction DD1, and the second emission area EA2 and the third emission area EA3 may be adjacent in a second diagonal direction DD2. Additionally, the first emission area EA1 and the fourth emission area EA4 may be adjacent in the second diagonal direction DD2, and the third emission area EA3 and the fourth emission area EA4 may be adjacent in the first diagonal direction DD1. The first diagonal direction DD1 may be a direction between the first direction DR1 and the second direction DR2, and may refer to a direction inclined by 45 degrees with respect to the first direction DR1 and the second direction DR2, and the second diagonal direction DD2 may be a direction perpendicular to the first diagonal direction DD1.

The first sub-pixel SP1 may emit a first light, the second sub-pixel SP2 may emit a second light, and the third sub-pixel SP3 may emit a third light. Here, the first light may be light of a blue wavelength band, the second light may be light of a green wavelength band, and the third light may be light of a red wavelength band. In an embodiment, for example, the blue wavelength band may be a wavelength band of light whose main peak wavelength is in a range of about 370 nanometers (nm) to about 460 nm, the green wavelength band may be a wavelength band of light whose main peak wavelength is in a range of about 480 nm to about 560 nm, and the red wavelength band may be a wavelength band of light whose main peak wavelength is in a range of about 600 nm to about 750 nm.

In embodiments, each of the plurality of pixels PX may include three emission areas EA1, EA2, and EA3 as shown in FIG. 7, or may include four emission areas EA1, EA2, EA3, and EA4 as shown in FIG. 8. In such embodiments, the fourth emission area EA4 may emit the same second light as the second emission area EA2, but the present disclosure is not limited thereto.

The emission areas of the plurality of pixels PX may be arranged in a stripe structure in which the emission areas are arranged in the first direction DR1, a PenTile® structure in which the emission areas EA1, EA2, EA3, and EA4 are arranged in a rhombic shape as shown in FIG. 8, or a hexagonal structure in which the emission areas are arranged in a hexagonal shape.

FIG. 9 is a schematic cross-sectional view illustrating an example of the display panel taken along line I1-I1′ shown in FIG. 7.

Referring to FIG. 9, an embodiment of the display panel 100 includes a semiconductor backplane SBP, a light emitting element backplane EBP, the display element layer EML, an encapsulation layer TFE, an optical layer OPL, a cover layer CVL, and a polarizing plate POL.

The semiconductor backplane SBP includes the semiconductor substrate SSUB including a plurality of pixel transistors PTR, a plurality of semiconductor insulating films covering the plurality of pixel transistors PTR, and a plurality of contact terminals CTE electrically connected to the plurality of pixel transistors PTR, respectively. The plurality of pixel transistors PTR may be the first to sixth transistors T1 to T6 described with reference to FIG. 5.

The semiconductor substrate SSUB may be a silicon substrate, a germanium substrate, or a silicon-germanium substrate. The semiconductor substrate SSUB may be a substrate doped with a first type impurity. A plurality of well regions WA may be disposed on the top surface of the semiconductor substrate SSUB. The plurality of well regions WA may be regions doped with a second type impurity. The second type impurity may be different from the first type impurity. In an embodiment, for example, where the first type impurity is a p-type impurity, the second type impurity may be an n-type impurity. In another embodiment, for example, where the first type impurity is an n-type impurity, the second type impurity may be a p-type impurity.

Each of the plurality of well regions WA includes a source region SA corresponding to the source electrode of the pixel transistor PTR, a drain region DA corresponding to the drain electrode thereof, and a channel region CH disposed between the source region SA and the drain region DA.

A lower insulating film BINS may be disposed between a gate electrode GE and the well region WA. A side insulating film SINS may be disposed on a side surface of the gate electrode GE. The side insulating film SINS may be disposed on the lower insulating film BINS.

Each of the source region SA and the drain region DA may be a region doped with the first type impurity. The gate electrode GE of the pixel transistor PTR may overlap the well region WA in the third direction DR3, which is a thickness direction of the display panel 100 or the semiconductor substrate SSUB. The channel region CH may overlap the gate electrode GE in the third direction DR3. The source region SA may be disposed on one side of the gate electrode GE, and the drain region DA may be disposed on the other side of the gate electrode GE.

Each of the plurality of well regions WA further includes a first low-concentration impurity region LDD1 disposed between the channel region CH and the source region SA, and a second low-concentration impurity region LDD2 disposed between the channel region CH and the drain region DA. The first low-concentration impurity region LDD1 may be a region having a lower impurity concentration than the source region SA due to the lower insulating film BINS. The second low-concentration impurity region LDD2 may be a region having a lower impurity concentration than the drain region DA due to the lower insulating film BINS. The distance between the source region SA and the drain region DA may increase due to the first low-concentration impurity region LDD1 and the second low-concentration impurity region LDD2, thereby increasing the length of the channel region CH of each of the pixel transistors PTR.

A first semiconductor insulating film SINS1 may be disposed on the semiconductor substrate SSUB. A second semiconductor insulating film SINS2 may be disposed on the first semiconductor insulating film SINS1.

The plurality of contact terminals CTE may be disposed on the second semiconductor insulating film SINS2. Each of the plurality of contact terminals CTE may be connected to a corresponding one of the gate electrode GE, the source region SA, and the drain region DA of each of the pixel transistors PTR through a hole penetrating (defined or formed through) the first semiconductor insulating film SINS1 and the second semiconductor insulating film SINS2. The plurality of contact terminals CTE may be formed of any one of copper (Cu), aluminum (Al), tungsten (W), molybdenum (Mo), chromium (Cr), gold (Au), titanium (Ti), nickel (Ni), and neodymium (Nd), or an alloy thereof.

A third semiconductor insulating film SINS3 may be disposed on a side surface of each of the plurality of contact terminals CTE. The top surface of each of the plurality of contact terminals CTE may be exposed without being covered by the third semiconductor insulating film SINS3.

Each of the first semiconductor insulating film SINS1, the second semiconductor insulating film SINS2, and the third semiconductor insulating film SINS3 may include or be formed of silicon carbonitride (SiCN) or a silicon oxide (SiOx)-based inorganic film, but the present disclosure is not limited thereto.

In an embodiment, the semiconductor substrate SSUB may be replaced with a glass substrate or a polymer resin substrate such as polyimide. In such an embodiment, thin film transistors may be disposed on the glass substrate or the polymer resin substrate. The glass substrate may be a rigid substrate that does not bend, and the polymer resin substrate may be a flexible substrate that can be bent or curved.

The light emitting element backplane EBP includes a plurality of conductive layers ML1 to ML8, a plurality of vias VA1 to VA9, and a plurality of interlayer insulating films INS1 to INS9.

The first to ninth interlayer insulating films INS1 to INS9 serve to insulate the first to eighth conductive layers ML1 to ML8. The first to eighth conductive layers ML1 to ML8 serve to connect the plurality of contact terminals CTE exposed from the semiconductor backplane SBP to thereby implement the circuit of the first sub-pixel SP1 shown in FIG. 5.

In an embodiment, for example, the first to sixth transistors T1 to T6 are merely formed in the semiconductor backplane SBP, and the connection of the first to sixth transistors T1 to T6 and the first and second capacitors C1 and C2 is accomplished through the first to eighth conductive layers ML1 to ML8. In addition, the connection between the drain region corresponding to the drain electrode of the fourth transistor T4, the source region corresponding to the source electrode of the fifth transistor T5, and a first electrode AND of the light emitting element LE is also accomplished through the first to eighth conductive layers ML1 to ML8.

The first to eighth conductive layers ML1 to ML8 and the first to eighth vias VA1 to VA8 may include or be formed of substantially a same material as each otehr. The first to eighth conductive layers ML1 to ML8 and the first to eighth vias VA1 to VA8 may include or be formed of at least one selected from copper (Cu), aluminum (Al), tungsten (W), molybdenum (Mo), chromium (Cr), gold (Au), titanium (Ti), nickel (Ni), and neodymium (Nd), or an alloy thereof. The first to eighth vias VA1 to VA8 may include or be made of substantially a same material as each other. First to eighth interlayer insulating films INS1 to INS8 may include or be formed of a silicon oxide (SiOx)-based inorganic layer, but the present disclosure is not limited thereto.

A ninth interlayer insulating film INS9 may be disposed on the eighth interlayer insulating film INS8 and the eighth conductive layer ML8. The ninth interlayer insulating film INS9 may include or be formed of a silicon oxide (SiOx)-based inorganic film, but the present disclosure is not limited thereto.

Each of the ninth vias VA9 may penetrate the ninth interlayer insulating film INS9 and be connected to the exposed eighth conductive layer ML8. The ninth vias VA9 may include or be formed of at least one selected from copper (Cu), aluminum (Al), tungsten (W), molybdenum (Mo), chromium (Cr), gold (Au), titanium (Ti), nickel (Ni), and neodymium (Nd), or an alloy thereof.

The display element layer EML may be disposed on the light emitting element backplane EBP. The display element layer EML may include the tenth and eleventh interlayer insulating films INS10 and INS11, reflective electrodes RL, the first electrodes AND, a light emitting stack IL, the second electrode CAT, a pixel defining film PDL, and a plurality of trenches TRC.

The reflective electrodes RL may be disposed on the ninth interlayer insulating film INS9. Each of the reflective electrodes RL may include at least one reflective electrode RL1, RL2, RL3, and RL4. In an embodiment, for example, each of the reflective electrodes RL may include the first to fourth reflective electrodes RL1, RL2, RL3, and RL4 as shown in FIG. 9.

The first reflective electrodes RL1 may be disposed on the ninth interlayer insulating film INS9, and may be connected to the ninth via VA9. Each of the second reflective electrodes RL2 may be disposed on the first reflective electrode RL1 corresponding thereto. Each of the third reflective electrodes RL3 may be disposed on the second reflective electrode RL2 corresponding thereto. Each of the fourth reflective electrodes RL4 may be disposed on the third reflective electrode RL3 corresponding thereto.

Since the second reflective electrode RL2 is an electrode that substantially reflects light from the light emitting elements LE, the thickness of the second reflective electrode RL2 may be greater than the thickness of each of the first reflective electrode RL1, the third reflective electrode RL3, and the fourth reflective electrode RL4.

The first reflective electrodes RL1 may include or be formed of at least one selected from copper (Cu), aluminum (Al), tungsten (W), molybdenum (Mo), chromium (Cr), gold (Au), titanium (Ti), nickel (Ni), and neodymium (Nd), or an alloy thereof. In an embodiment, for example, the first reflective electrodes RL1 may contain titanium nitride (TiN), the second reflective electrodes RL2 may contain aluminum (Al), the third reflective electrodes RL3 may contain titanium nitride (TiN), and the fourth reflective electrodes RL4 may include titanium (Ti).

The tenth interlayer insulating film INS10 may be disposed on the ninth interlayer insulating film INS9. The tenth interlayer insulating film INS10 may be disposed between the reflective electrodes RL adjacent to each other. The tenth interlayer insulating film INS10 may be a film for flattening a stepped portion caused by the reflective electrodes RL. The eleventh interlayer insulating film INS11 may be disposed on the tenth interlayer insulating film INS10 and the reflective electrodes RL.

The tenth interlayer insulating film INS10 and the eleventh interlayer insulating film INS11 may include or be formed of a silicon oxide (SiOx)-based inorganic film, but the present disclosure is not limited thereto.

The eleventh interlayer insulating film INS11 may be an optical auxiliary layer for adjusting the resonance distance of light emitted from the light emitting stack IL in at least one of the first sub-pixel SP1, the second sub-pixel SP2, or the third sub-pixel SP3. The thickness of the eleventh interlayer insulating film INS11 may be different in the first sub-pixel SP1, the second sub-pixel SP2, and the third sub-pixel SP3. That is, in order to adjust a distance from the reflective electrode RL to the second electrode CAT according to a main wavelength of light emitted from each of the first sub-pixel SP1, the second sub-pixel SP2, and the third sub-pixel SP3, the thickness of the eleventh interlayer insulating film INS11 may be set for each of the first sub-pixel SP1, the second sub-pixel SP2, and the third sub-pixel SP3.

In an embodiment, for example, as shown in FIG. 9, the thickness of the eleventh interlayer insulating film INS11 in the first sub-pixel SP1 may be greater than the thickness of the eleventh interlayer insulating film INS11 in the second sub-pixel SP2, and the thickness of the eleventh interlayer insulating film INS11 in the second sub-pixel SP2 may be greater than the thickness of the eleventh interlayer insulating film INS11 in the third sub-pixel SP3. In such an embodiment, the distance between the first electrode AND and the reflective electrode RL in the first sub-pixel SP1 is greater than the distance between the first electrode AND and the reflective electrode RL in the second sub-pixel SP2. In addition, the distance between the first electrode AND and the reflective electrode RL in the second sub-pixel SP2 is greater than the distance between the first electrode AND and the reflective electrode RL in the third sub-pixel SP3.

Each of the tenth vias VA10 may penetrate the eleventh interlayer insulating film INS11 and be connected to the exposed fourth reflective electrode RL4. The tenth vias VA10 may include or be formed of at least one selected from copper (Cu), aluminum (Al), tungsten (W), molybdenum (Mo), chromium (Cr), gold (Au), titanium (Ti), nickel (Ni), and neodymium (Nd), or an alloy thereof. The thickness of the tenth via VA10 in the first sub-pixel SP1 may be greater than the thickness of the tenth via VA10 in the second sub-pixel SP2, and the thickness of the tenth via VA10 in the second sub-pixel SP2 may be greater than the thickness of the tenth via VA10 in the third sub-pixel SP3.

The first electrode AND of each of the light emitting elements LE may be disposed on the eleventh interlayer insulating film INS11 and connected to the tenth via VA10. The first electrode AND of each of the light emitting elements LE may be connected to the drain region DA or source region SA of the pixel transistor PTR through the tenth via VA10, the reflective electrode RL, the first to ninth vias VA1 to VA9, the first to eighth metal layers ML1 to ML8, and the contact terminal CTE. The first electrode AND of each of the light emitting elements LE may include or be formed of at least one selected from copper (Cu), aluminum (Al), tungsten (W), molybdenum (Mo), chromium (Cr), gold (Au), titanium (Ti), nickel (Ni), and neodymium (Nd), or an alloy thereof. For example, the first electrode AND of each of the light emitting elements LE may be titanium nitride (TiN).

The pixel defining film PDL may be disposed on a part of the first electrode AND of each of the light emitting elements LE. The pixel defining film PDL may cover the edge of the first electrode AND of each of the light emitting elements LE. The pixel defining film PDL may partition the first emission areas EA1, the second emission areas EA2, and the third emission areas EA3. Each of the first emission area EA1, the second emission area EA2, and the third emission area EA3 may be an area where the light emitting element LE including the first electrode AND, the light emitting stack IL, and the second electrode CAT is disposed.

The first emission area EA1 may be defined as an area in which the first electrode AND, the light emitting stack IL, and the second electrode CAT are sequentially stacked in the first sub-pixel SP1 to emit light. The second emission area EA2 may be defined as an area in which the first electrode AND, the light emitting stack IL, and the second electrode CAT are sequentially stacked in the second sub-pixel SP2 to emit light. The third emission area EA3 may be defined as an area in which the first electrode AND, the light emitting stack IL, and the second electrode CAT are sequentially stacked in the third sub-pixel SP3 to emit light.

The pixel defining film PDL may include first to third pixel defining films PDL1, PDL2, and PDL3. The first pixel defining film PDL1 may be disposed on the edge of the first electrode AND of each of the light emitting elements LE, the second pixel defining film PDL2 may be disposed on the first pixel defining film PDL1, and the third pixel defining film PDL3 may be disposed on the second pixel defining film PDL2. The first pixel defining film PDL1, the second pixel defining film PDL2, and the third pixel defining film PDL3 may include or be formed of a silicon oxide (SiOx)-based inorganic film. Alternatively, the first pixel defining film PDL1 and the third pixel defining film PDL3 may be formed of a silicon nitride (SiNx)-based inorganic film, whereas the second pixel defining film PDL2 may be formed of a silicon oxide (SiOx)-based inorganic film. The first pixel defining film PDL1, the second pixel defining film PDL2, and the third pixel defining film PDL3 may each have a thickness of about 500 angstrom (Å).

In an embodiment, to reduce or prevent the likelihood of the first encapsulation inorganic film TFE1 being cut off due to the step coverage, the first pixel defining film PDL1, the second pixel defining film PDL2, and the third pixel defining film PDL3 may have a cross-sectional structure having a stepped portion. Step coverage refers to the ratio of the degree of thin film coated on an inclined portion to the degree of thin film coated on a flat portion. The lower the step coverage, the more likely it is that the thin film will be cut off at inclined portions.

Each of the plurality of trenches TRC may penetrate the first pixel defining film PDL1, the second pixel defining film PDL2, and the third pixel defining film PDL3. The eleventh interlayer insulating film INS11 may be partially recessed at each of the plurality of trenches TRC.

At least one trench TRC may be defined between the neighboring sub-pixels SP1, SP2, and SP3. Although FIG. 9 illustrates an embodiment where two trenches TRC are disposed between the neighboring sub-pixels SP1, SP2, and SP3, the present disclosure is not limited thereto.

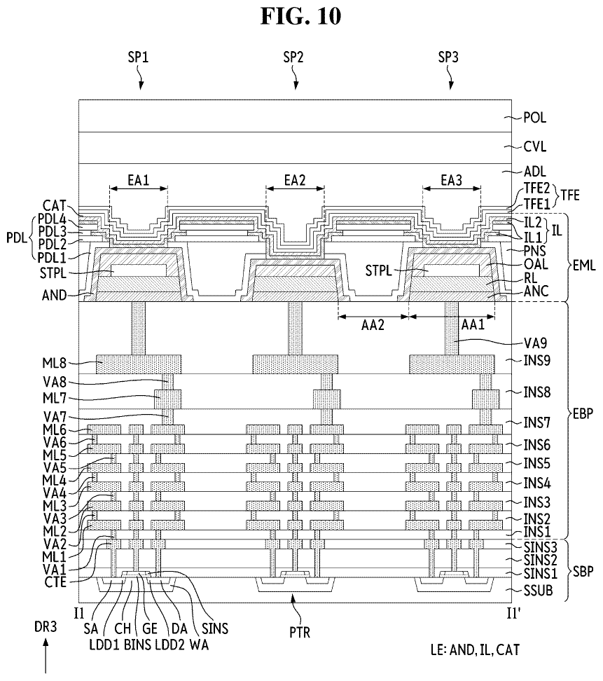

The light emitting stack IL may include a plurality of stack layers IL1, IL2, and IL3. FIG. 9 illustrates an embodiment where the light emitting stack IL has a three-tandem structure including a first stack layer IL1, a second stack layer IL2, and a third stack layer IL3, but the present disclosure is not limited thereto. In another embodiment, for example, the light emitting stack IL may have a two-tandem structure including two stack layers as shown in FIG. 10.

In the three-tandem structure, the light emitting stack IL may have a tandem structure including a plurality of intermediate layers IL1, IL2, and IL3 that emit different lights. In an embodiment, for example, the light emitting stack IL may include the first stack layer IL1 that emits first light, the second stack layer IL2 that emits second light, and the third stack layer IL3 that emits third light. The first stack layer IL1, the second stack layer IL2, and the third stack layer IL3 may be sequentially stacked.

The first stack layer IL1 may have a structure in which a first hole transport layer, a first light emitting layer that emits the first light, and a first electron transport layer are sequentially stacked. The second stack layer IL2 may have a structure in which a second hole transport layer, a second light emitting layer that emits the second light, and a second electron transport layer are sequentially stacked. The third stack layer IL3 may have a structure in which a third hole transport layer, a third light emitting layer that emits the third light, and a third electron transport layer are sequentially stacked.

A first charge generation layer for supplying charges to the second stack layer IL2 and supplying electrons to the first stack layer IL1 may be disposed between the first stack layer IL1 and the second stack layer IL2. The first charge generation layer may include an N-type charge generation layer that supplies electrons to the first stack layer IL1 and a P-type charge generation layer that supplies holes to the second stack layer IL2. The N-type charge generation layer may include a dopant of a metal material.

A second charge generation layer for supplying charges to the third stack layer IL3 and supplying electrons to the second stack layer IL2 may be disposed between the second stack layer IL2 and the third stack layer IL3. The second charge generation layer may include an N-type charge generation layer that supplies electrons to the second stack layer IL2 and a P-type charge generation layer that supplies holes to the third stack layer IL3.

The first stack layer IL1 may be disposed on the first electrodes AND and the pixel defining film PDL, and a residual film RIL disposed on the bottom surface of each trench TRC may be the same material as the first stack layer IL1. Due to the trench TRC, the first stack layer IL1 may be cut off between the neighboring sub-pixels SP1, SP2, and SP3. The second stack layer IL2 may be disposed on the first stack layer IL1. Due to the trench TRC, the second stack layer IL2 may be cut off between the neighboring sub-pixels SP1, SP2, and SP3. A cavity ESS or an empty space may be disposed between the residual film IL and the second stack layer IL2 in the trench TRC. The third stack layer IL3 may be disposed on the second stack layer IL2. The third stack layer IL3 is not cut off by the trench TRC and may be disposed to cover the second stack layer IL2 in each of the trenches TRC.

In the three-tandem structure, each of the plurality of trenches TRC may be a structure for cutting off the first to third hole transport layers, the first charge generation layer, and the second charge generation layer of the first to third stack layers IL1, IL2, and IL3 of the display element layer EML between the neighboring sub-pixels SP1, SP2, and SP3. In addition, in the two-tandem structure, each of the plurality of trenches TRC may be a structure for cutting off the charge generation layer and the lower stack layer disposed between the lower stack layer and the upper stack layer.

In an embodiment, to stably cut off the first and second stack layers IL1 and IL2 of the display element layer EML between the neighboring sub-pixels SP1, SP2, and SP3, the height of each of the plurality of trenches TRC may be greater than the height of the pixel defining film PDL. The height of each of the plurality of trenches TRC refers to the length of each of the plurality of trenches TRC in the third direction DR3. The height of the pixel defining film PDL refers to the length of the pixel defining film PDL in the third direction DR3. In an embodiment, to cut off the charge generation layers and the hole transport layers of the light emitting stack IL of the display element layer EML between the neighboring sub-pixels SP1, SP2, and SP3, a different structure may be present instead of the trench TRC. In an embodiment, for example, instead of the trench TRC, a reverse tapered partition wall may be disposed on the pixel defining film PDL.

In addition, FIG. 9 illustrates an embodiment where the light emitting stack IL that emits light is disposed in the first emission area EA1, the second emission area EA2, and the third emission area EA3, but the present disclosure is not limited thereto. In another embodiment, for example, instead of the light emitting stack IL, the first light emitting layer may be disposed in the first emission area EA1, and may be omitted from the second emission area EA2 and the third emission area EA3. Furthermore, the second light emitting layer may be disposed in the second emission area EA2 and may be omitted from the first emission area EA1 and the third emission area EA3. Furthermore, the third light emitting layer may be disposed in the third emission area EA3 and may be omitted from the first emission area EA1 and the second emission area EA2. In such an embodiment, first to third color filters CF1, CF2, and CF3 of the optical layer OPL may be omitted.

The second electrode CAT may be disposed on the light emitting stack IL. That is, the second electrode CAT may be disposed on the third stack layer IL3. The second electrode CAT may include or be formed of a transparent conductive material (TCO) such as ITO or IZO that can transmit light or a semi-transmissive conductive material such as magnesium (Mg), silver (Ag), or an alloy of Mg and Ag. In an embodiment where the second electrode CAT is formed of a semi-transmissive conductive material, the light emission efficiency may be improved in each of the first to third sub-pixels SP1, SP2, and SP3 due to a micro-cavity effect.

The encapsulation layer TFE may be disposed on the display element layer EML. The encapsulation layer TFE may include at least one inorganic film TFE1 and TFE3 to prevent oxygen or moisture from permeating into the display element layer EML. The first encapsulation inorganic film TFE1 may be disposed on the second electrode CAT, and the second encapsulation inorganic film TFE3 may be disposed above the first encapsulation inorganic film TFE1. The first encapsulation inorganic film TFE1 and the second encapsulation inorganic film TFE3 may be formed of or defined by multiple layers in which one or more inorganic films of silicon nitride (SiNx), silicon oxynitride (SiON), silicon oxide (SiOx), titanium oxide (TiOx), and aluminum oxide (AlOx) layers are alternately stacked.

In addition, the encapsulation layer TFE may include at least one organic film TFE2 to protect the display element layer EML from foreign substances such as dust. The encapsulating organic film TFE2 may be disposed between the first encapsulating inorganic film TFE1 and the second encapsulating inorganic film TFE3. The encapsulation organic film TFE2 may be a monomer. Alternatively, the encapsulation organic film TFE2 may be an organic film such as acryl resin, epoxy resin, phenolic resin, polyamide resin, polyimide resin or the like.

An adhesive layer ADL may be a layer for bonding the encapsulation layer TFE to the optical layer OPL. The adhesive layer ADL may be a double-sided adhesive member. In addition, the adhesive layer ADL may be a transparent adhesive member such as a transparent adhesive or a transparent adhesive resin.

The optical layer OPL includes a plurality of color filters CF1, CF2, and CF3, a plurality of lenses LNS, and a filling layer FIL. The plurality of color filters CF1, CF2, and CF3 may include the first to third color filters CF1, CF2, and CF3. The first to third color filters CF1, CF2, and CF3 may be disposed on the adhesive layer ADL.

The first color filter CF1 may overlap the first emission area EA1 of the first sub-pixel SP1. The first color filter CF1 may transmit light of the first color, i.e., light of a blue wavelength band. The blue wavelength band may be about 370 nm to about 460 nm. Thus, the first color filter CF1 may transmit light of the first color among light emitted from the first emission area EA1.

The second color filter CF2 may overlap the second emission area EA2 of the second sub-pixel SP2. The second color filter CF2 may transmit light of the second color, i.e., light of a green wavelength band. The green wavelength band may be about 480 nm to about 560 nm. Thus, the second color filter CF2 may transmit light of the second color among light emitted from the second emission area EA2.

The third color filter CF3 may overlap the third emission area EA3 of the third sub-pixel SP3. The third color filter CF3 may transmit light of the third color, i.e., light of a red wavelength band. The red wavelength band may be about 600 nm to about 750 nm. Thus, the third color filter CF3 may transmit light of the third color among light emitted from the third emission area EA3.

The plurality of lenses LNS may be disposed on the first color filter CF1, the second color filter CF2, and the third color filter CF3, respectively. Each of the plurality of lenses LNS may be a structure for increasing the proportion of light directed to the front of the display device 10. Each of the plurality of lenses LNS may have a cross-sectional shape that is convex in an upward direction.

The filling layer FIL may be disposed on the plurality of lenses LNS. The filling layer FIL may have a predetermined refractive index such that light travels in the third direction DR3 at an interface between the filling layer FIL and the plurality of lenses LNS. Further, the filling layer FIL may be a planarization layer. The filling layer FIL may be an organic film such as acrylic resin, epoxy resin, phenolic resin, polyamide resin, or polyimide resin.

The cover layer CVL may be disposed on the filling layer FIL. The cover layer CVL may be a glass substrate or a polymer resin. In an embodiment where the cover layer CVL is a glass substrate, it may be attached onto the filling layer FIL. In such an embodiment, the filling layer FIL may serve to bond the cover layer CVL. In an embodiment where the cover layer CVL is a glass substrate, it may serve as an encapsulation substrate. In an embodiment where the cover layer CVL is a polymer resin, it may be directly applied onto the filling layer FIL.

The polarizing plate may be disposed on one surface of the cover layer CVL. The polarizing plate may be a structure for reducing or preventing visibility degradation caused by reflection of external light. The polarizing plate may include a linear polarizing plate and a phase retardation film. In an embodiment, for example, the phase retardation film may be a λ/4 plate (quarter-wave plate), but the present disclosure is not limited thereto. However, when visibility degradation caused by reflection of external light is sufficiently overcome by the first to third color filters CF1, CF2, and CF3, the polarizing plate may be omitted.

FIG. 10 is a schematic cross-sectional view illustrating another example of the display panel taken along line I1-I1′ shown in FIG. 7.

The embodiment of FIG. 10 is substantially the same as the embodiment of FIG. 9 except that the first electrode AND of each of the light emitting elements LE is in contact with and electrically connected to the side surface of a connection electrode ANC connected to the eighth conductive layer ML8, and that the trench TRC is omitted, and instead, the third pixel defining film PDL3 and a fourth pixel defining film PDL4 have an eave-shaped or mushroom-shaped cross-sectional structure. In description of the embodiment of FIG. 10, any repetitive detailed description of the same or like elements as those of the embodiment of FIG. 9 will be omitted.

Referring to FIG. 10, the plurality of connection electrodes ANC may be respectively disposed on first portions AA1 of the ninth interlayer insulating film INS9. Each of the plurality of connection electrodes ANC may be disposed on the first portion AA1 of the ninth interlayer insulating film INS9 corresponding thereto. A plurality of connection electrodes ANC may include ro be formed of at least one selected from copper (Cu), aluminum (Al), tungsten (W), molybdenum (Mo), chromium (Cr), gold (Au), titanium (Ti), nickel (Ni), and neodymium (Nd), an alloy thereof, or a transparent conductive oxide. In an embodiment, for example, the plurality of connection electrodes ANC may include titanium (Ti), titanium nitride (TiN), indium tin oxide (ITO), or indium zinc oxide (IZO), but the present disclosure is limited thereto.

A plurality of reflective electrodes RL may be respectively disposed on the plurality of connection electrodes ANC. Each of the plurality of reflective electrodes RL may be disposed on the connection electrode ANC corresponding thereto. The plurality of reflective electrodes RL may include or be formed of at least one selected from copper (Cu), aluminum (Al), tungsten (W), molybdenum (Mo), chromium (Cr), gold (Au), titanium (Ti), nickel (Ni), and neodymium (Nd), or an alloy thereof. In an embodiment, for example, each of the plurality of reflective electrodes RL may include aluminum (Al) having high reflectivity.

A plurality of optical auxiliary films OAL may be respectively disposed on the plurality of reflective electrodes RL. Each of the plurality of optical auxiliary films OAL may be disposed on the reflective electrode RL corresponding thereto. The plurality of optical auxiliary films OAL may be formed of a silicon oxide (SiOx)-based inorganic film, but the present disclosure is not limited thereto.

In each of the first emission area EA1 and the third emission area EA3, a step layer STPL may be disposed on the reflective electrode RL, and the optical auxiliary film OAL may be disposed on the step layer STPL. In the second emission area EA2, only the optical auxiliary film OAL may be disposed on the reflective electrode RL. The thicknesses of the optical auxiliary film OAL may be substantially the same in the first emission area EA1, the second emission area EA2, and the third emission area EA3.

Due to the step layer STPL, the distance between the reflective electrode RL and the first electrode AND in the first emission area EA1 and the third emission area EA3 may be greater than the distance between the reflective electrode RL and the first electrode AND in the second emission area EA2. The thickness of the step layer STPL and the thickness of the optical auxiliary layer OAL may be set in consideration of the wavelength and resonance distance of light emitted from the first stack layer IL1 of the light emitting stack IL, and the wavelength and resonance distance of light emitted from the second stack layer IL2 thereof.

Each of the light emitting elements LE may include the first electrode AND, a light emitting stack IL, and a second electrode CAT.

The first electrode AND of each of the light emitting elements LE may be disposed on the optical auxiliary film OAL corresponding thereto. In such an embodiment, the connection electrode ANC, the reflective electrode RL, and the optical auxiliary layer OAL are sequentially stacked, such that the first electrode AND of each of the light emitting elements LE may be disposed on the top surface and the side surface of the optical auxiliary layer OAL, the side surface of the reflective electrode RL, and the side surface of the connection electrode ANC. Accordingly, the first electrode AND of each of the light emitting elements LE may be in contact with and electrically connected to the side surface of the reflective electrode RL and the side surface of the connection electrode ANC. Therefore, compared to a case where the first electrode AND of each of the light emitting elements LE is connected to the reflective electrode RL exposed through a through hole penetrating the optical auxiliary film OAL, the number of mask processes may be reduced, thereby lowering manufacturing cost and increasing manufacturing efficiency.

The first electrode AND of each of the light emitting elements LE may be connected to the drain region DA or the source region SA of the pixel transistor PTR through the connection electrode ANC, the first to ninth vias VA1 to VA9, the first to eighth conductive layers ML1 to ML8, and the contact terminal CTE.

The ninth interlayer insulating film INS9 may include the first portion AA1 that overlaps the connection electrode ANC in the third direction DR3 and a second portion AA2 that does not overlap the connection electrode ANC in the third direction DR3. The thickness of the first portion AA1 and the thickness of the second portion AA2 of the ninth interlayer insulating film INS9 may be substantially the same as each other.

Alternatively, the thickness of the first portion AA1 of the ninth interlayer insulating film INS9 may be greater than the thickness of the second portion AA2 thereof. In this case, the side surface of the first portion AA1 of the ninth interlayer insulating film INS9 may be exposed, and the first electrode AND of each of the light emitting elements LE may be disposed on the exposed side surface of the first portion AA1 of the ninth interlayer insulating film INS9.

The first electrode AND of each of the light emitting elements LE may include or be formed of at least one selected from copper (Cu), aluminum (Al), tungsten (W), molybdenum (Mo), chromium (Cr), gold (Au), titanium (Ti), nickel (Ni), and neodymium (Nd), an alloy thereof, or a transparent conductive oxide. In an embodiment, for example, the first electrode AND of each of the light emitting elements LE may include titanium (Ti), titanium nitride (TiN), indium tin oxide (ITO), or indium zinc oxide (IZO), but the present disclosure is limited thereto.

The pixel defining film PDL may be disposed on a part of the first electrode AND of each of the light emitting elements LE. The pixel defining film PDL may cover the edge of the first electrode AND of each of the light emitting elements LE. The pixel defining film PDL may partition the first emission areas EA1, the second emission areas EA2, and the third emission areas EA3.

The pixel defining film PDL may include first to fourth pixel defining films PDL1, PDL2, PDL3, and PDL4.

The first pixel defining film PDL1 may be disposed on the first electrode AND of each of the light emitting elements LE. Specifically, the first pixel defining film PDL1 may cover a part of the top surface of the first electrode AND disposed on the optical auxiliary film OAL. Further, the first pixel defining film PDL1 may cover the first electrode AND disposed on the side surface of the connection electrode ANC, the side surface of the reflective electrode RL, and the side surface of the optical auxiliary film OAL. The first pixel defining film PDL1 may be disposed on the top surface of the second portion AA2 of the ninth interlayer insulating film INS9.

A planarization film PNS is a film for flattening the stepped portion caused by the connection electrode ANC, the reflective electrode RL, and the optical auxiliary film OAL.

The planarization film PNS may be disposed on the first pixel defining film PDL1 covering the first electrode AND disposed on the side surface of the connection electrode ANC, the side surface of the reflective electrode RL, and the side surface of the optical auxiliary film OAL. The planarization film PNS may be disposed on the first pixel defining film PDL1 disposed on the second portion AA2 of the ninth interlayer insulating film INS9.

The planarization film PNS may be disposed between the connection electrodes ANC adjacent in the first direction DR1 or the second direction DR2. The planarization film PNS may be disposed between the reflective electrodes RL adjacent in the first direction DR1 or the second direction DR2. The planarization film PNS may be disposed between the optical auxiliary films OAL adjacent in the first direction DR1 or the second direction DR2.

The step layer STPL is not present in the second emission area EA2, whereas the step layer STPL is present in each of the first emission area EA1 and the third emission area EA3. Accordingly, the heights of the connection electrode ANC, the reflective electrode RL, and the optical auxiliary film OAL in the second emission area EA2 may be less than the heights of the connection electrode ANC, the reflective electrode RL, the step layer STPL, and the optical auxiliary film OAL in the first emission area EA1 and the third emission area EA3. Therefore, the planarization film PNS may cover the top surface of the first pixel defining film PDL1 disposed on the top surface of the first electrode AND disposed in the second emission area EA2.

In another embodiment, the top surface of the planarization film PNS may be flatly connected to the top surface of the first pixel defining film PDL1 disposed on the top surface of the first electrode AND disposed in the first emission area EA1 and the third emission area EA3. That is, the planarization film PNS may not cover the top surface of the first pixel defining film PDL1 disposed on the top surface of the first electrode AND disposed in each of the first emission area EA1 and the third emission area EA3.

The second pixel defining film PDL2 may be disposed on the first pixel defining film PDL1 and the planarization film PNS, the third pixel defining film PDL3 may be disposed on the second pixel defining film PDL2, and the fourth pixel defining film PDL4 may be disposed on the third pixel defining film PDL3. The first pixel defining film PDL1 and the third pixel defining film PDL3 may include or be formed of a silicon nitride (SiNx)-based inorganic film, whereas the second pixel defining film PDL2, the fourth pixel defining film PDL4, and the planarization film PNS may include or be formed of a silicon oxide (SiOx)-based inorganic film. The first pixel defining film PDL1 is formed of a material different from that of the planarization film PNS, and thus may serve as a stopper in a chemical mechanical polishing process for the planarization film PNS.

In an embodiment where the planarization film PNS and the second pixel defining film PDL2 are both formed as a silicon oxide (SiOx)-based inorganic film, the planarization film PNS and the second pixel defining film PDL2 may be formed as a single film.

Since the length of the third pixel defining film PDL3 in one direction is less than the length of the fourth pixel defining film PDL4 in one direction, the bottom surface of the fourth pixel defining film PDL4 may be exposed without being covered by the third pixel defining film PDL3. That is, the third pixel defining film PDL3 and the fourth pixel defining film PDL4 may have an eaves-shaped or mushroom-shaped cross-sectional structure.

The light emitting stack IL may be disposed on the first electrode AND and the pixel defining film PDL. The light emitting stack IL may include the first stack layer IL1 and the second stack layer IL2 that emit different lights from each other. In an embodiment where the light emitting stack IL has a two-tandem structure, one of the first stack layer IL1 and the second stack layer IL2 may emit light that includes the wavelength range of one of the first light, the second light, and the third light, and the other may emit light that includes the wavelength ranges of the other two thereof. In an embodiment, for example, the first stack layer IL1 may emit light that includes the wavelength range of the first light and the wavelength range of the third light, and the second stack layer IL2 may emit light that includes the wavelength range of the second light. Here, the first light may be light of a blue wavelength band, the second light may be light of a green wavelength band, and the third light may be light of a red wavelength band.

A charge generation layer for supplying charges to the second stack layer IL2 and supplying electrons to the first stack layer IL1 may be disposed between the first stack layer IL1 and the second stack layer IL2. The charge generation layer may include an n-type charge generation layer that supplies electrons to the first stack layer IL1 and a p-type charge generation layer that supplies holes to the second stack layer IL2. The N-type charge generation layer may include a dopant of a metal material.

In an embodiment, the first stack layer IL1 is not formed on the bottom surface of the fourth pixel defining film PDL4 that is exposed without being covered by the third pixel defining film PDL3, and thus may be cut off by the eaves-shaped or mushroom-shaped cross-sectional structure of the third pixel defining film PDL3 and the fourth pixel defining film PDL4. In such an embodiment, the first hole transport layer of the first stack layer IL1, and a charge generation layer disposed between the first stack layer IL1 and the second stack layer IL2 may also be cut off. Further, although FIG. 10 illustrates an embodiment where the second stack layer IL2 is connected without being cut off, the second hole transport layer of the second stack layer IL2 may be cut off, and the second electron transport layer of the second stack layer IL2 may be connected without being cut off. Therefore, it is possible to effectively prevent a leakage current from flowing through the first hole transport layer of the first stack layer IL1, the second hole transport layer of the second stack layer IL2, and the charge generation layer between the adjacent emission areas EA1, EA2, and EA3. Accordingly, it is possible to effectively prevent the light emitting stack IL in the adjacent emission areas EA1, EA2, and EA3 from emitting light other than the originally intended light due to the influence of the above current.

Although FIG. 10 illustrates an embodiment where the light emitting stack IL has a two-tandem structure in which the light emitting stack IL includes two stack layers IL1 and IL2, the present disclosure is not limited thereto. In an embodiment, for example, the light emitting stack IL may have a three-tandem structure including three stack layers as shown in FIG. 9. In such an embodiment, it may be designed such that the charge generation layer between the first stack layer IL1 and the second stack layer IL2, and the charge generation layer between the second stack layer IL2 and the third stack layer IL3 are cut off by adjusting the height of the third pixel defining film PDL3. Alternatively, as shown in FIG. 9, the trench TRC penetrating the first pixel defining film PDL1, the planarization film PNS, the second pixel defining film PDL2, and the third pixel defining film PDL3 may be added. In this case, the trench TRC may penetrate at least a part of the ninth interlayer insulating film INS9, but the present disclosure is not limited thereto.

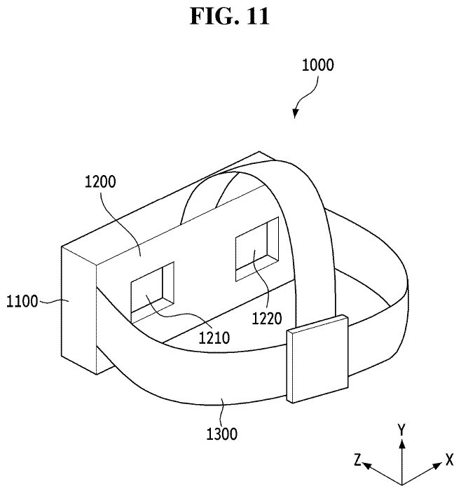

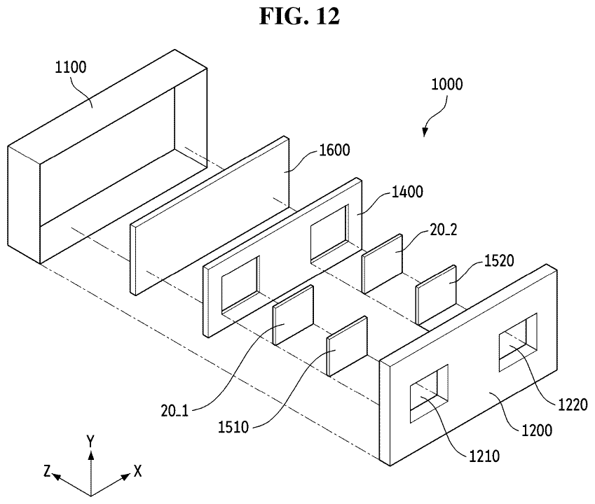

FIG. 11 is a schematic perspective view illustrating one example of a head mounted display. FIG. 12 is a schematic exploded perspective view illustrating the head mounted display shown in FIG. 11.

Referring to FIGS. 11 and 12, a head mounted display 1000 according to an embodiment includes a first display device 20_1, a second display device 20_2, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

The first display device 20_1 provides an image to the user's left eye, and the second display device 20_2 provides an image to the user's right eye. Since each of the first display device 20_1 and the second display device 20_2 is substantially the same as the display device 20 described in conjunction with FIGS. 3 to 10, any repetitive detailed description of the first display device 20_1 and the second display device 20_2 will be omitted.

The first optical member 1510 may be disposed between the first display device 20_1 and the first eyepiece 1210. The second optical member 1520 may be disposed between the second display device 20_2 and the second eyepiece 1220. Each of the first optical member 1510 and the second optical member 1520 may include at least one convex lens.

The middle frame 1400 may be disposed between the first display device 20_1 and the control circuit board 1600 and between the second display device 20_2 and the control circuit board 1600. The middle frame 1400 serves to support and fix the first display device 20_1, the second display device 20_2, and the control circuit board 1600.

The control circuit board 1600 may be disposed between the middle frame 1400 and the display device housing 1100. The control circuit board 1600 may be connected to the first display device 20_1 and the second display device 20_2 through the connector. The control circuit board 1600 may convert an image source inputted from the outside into the digital video data, and transmit the digital video data to the first display device 20_1 and the second display device 20_2 through the connector.

The control circuit board 1600 may transmit the digital video data corresponding to a left-eye image optimized for the user's left eye to the first display device 20_1, and may transmit the digital video data corresponding to a right-eye image optimized for the user's right eye to the second display device 20_2. Alternatively, the control circuit board 1600 may transmit the same digital video data to the first display device 20_1 and the second display device 20_2.

The display device housing 1100 serves to accommodate the first display device 20_1, the second display device 20_2, the middle frame 1400, the first optical member 1510, the second optical member 1520, and the control circuit board 1600. The housing cover 1200 is disposed to cover one open surface of the display device housing 1100. The housing cover 1200 may include the first eyepiece 1210 at which the user's left eye is located and the second eyepiece 1220 at which the user's right eye is located. FIGS. 11 and 12 illustrate an embodiment where the first eyepiece 1210 and the second eyepiece 1220 are disposed separately, but the present disclosure is not limited thereto. The first eyepiece 1210 and the second eyepiece 1220 may be combined into one.

The first eyepiece 1210 may be aligned with the first display device 20_1 and the first optical member 1510, and the second eyepiece 1220 may be aligned with the second display device 20_2 and the second optical member 1520. Therefore, the user may view, through the first eyepiece 1210, the image of the first display device 20_1 magnified as a virtual image by the first optical member 1510, and may view, through the second eyepiece 1220, the image of the second display device 20_2 magnified as a virtual image by the second optical member 1520.

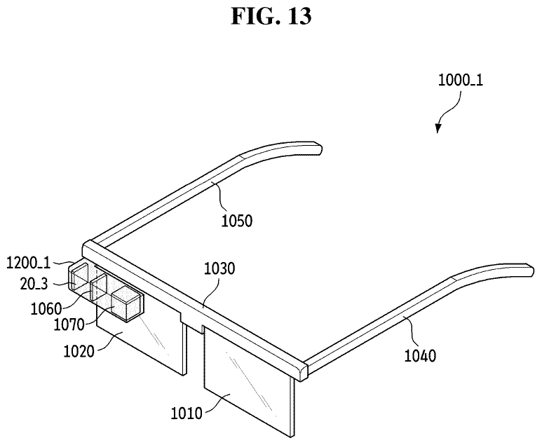

The head mounted band 1300 serves to secure the display device housing 1100 to the user's head such that the first eyepiece 1210 and the second eyepiece 1220 of the housing cover 1200 remain located on the user's left and right eyes, respectively. In an embodiment where the display device housing 1200 is desired to be implemented to be lightweight and compact, the head mounted display 1000 may be provided with, as shown in FIG. 13, an eyeglass frame instead of the head mounted band 1300.

FIG. 13 is a schematic perspective view illustrating another example of a head mounted display.

Referring to FIG. 13, a head mounted display 1000_1 according to an embodiment may be an eyeglasses-type display device in which a display device housing 1200_1 is implemented in a lightweight and compact manner. The head mounted display 1000_1 according to an embodiment may include a display device 20_3, a left eye lens 1010, a right eye lens 1020, a support frame 1030, temples 1040 and 1050, an optical member 1060, an optical path changing member 1070, and the display device housing 1200_1.

The display device housing 1200_1 may include the display device 20_3, the optical member 1060, and the optical path changing member 1070. The image displayed on the display device 20_3 may be magnified by the optical member 1060, and may be provided to the user's right eye through the right eye lens 1020 after the optical path thereof is changed by the optical path changing member 1070. As a result, the user may view an augmented reality image, through the right eye, in which a virtual image displayed on the display device 20_3 and a real image seen through the right eye lens 1020 are combined.

FIG. 13 illustrates an embodiment where the display device housing 1200_1 is disposed at the right end of the support frame 1030, but the present disclosure is not limited thereto. In another embodiment, for example, the display device housing 1200_1 may be disposed at the left end of the support frame 1030, and in such an embodiment, the image of the display device 20_3 may be provided to the user's left eye. Alternatively, the display device housing 1200_1 may be disposed at both the left and right ends of the support frame 1030, and in such an embodiment, the user may view the image displayed on the display device 20_3 through both the left and right eyes.

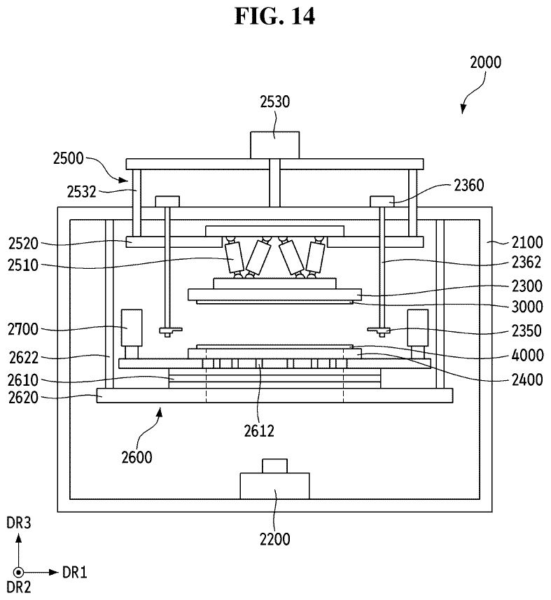

FIG. 14 is a schematic diagram illustrating a deposition mask and a deposition apparatus including the deposition mask according to an embodiment of the present disclosure.

Referring to FIG. 14, an embodiment of a deposition apparatus 2000 may be used to form light emitting layers on a backplane substrate 3000 in a manufacturing process of the display panel 100 (see FIG. 3). In an embodiment, for example, as illustrated in FIG. 9, the semiconductor backplane SBP and the light emitting element backplane EBP may be disposed on the backplane substrate 3000, and the reflective electrode layer RL and the insulating films INS10 and INS11 may be disposed on the light emitting element backplane EBP. Electrode patterns, e.g., the first electrodes AND that function as anode electrodes, and the pixel defining film PDL that exposes the first electrodes AND, may be arranged on the insulating film INS11, and the first electrodes AND may be electrically connected to the reflective electrode layer RL through the vias VA10. In an embodiment, for example, the deposition apparatus 2000 may form first light emitting layers on the first electrodes AND of the first emission areas EA1. In an embodiment, for example, the deposition apparatus 2000 may form second light emitting layers on the first electrodes AND of the second emission areas EA1. In an embodiment, for example, the deposition apparatus 2000 may form third light emitting layers on the first electrodes AND of the third emission areas EA3.

The deposition apparatus 2000 may include a deposition source 2200 for providing a vapor deposition material onto the backplane substrate 3000, a substrate chuck 2300 for supporting the backplane substrate 3000 to face the deposition source 2200, and a mask chuck 2400 disposed between the deposition source 2200 and the substrate chuck 2300 to support the deposition mask 4000 to face the backplane substrate 3000. The deposition source 2200, the substrate chuck 2300, and the mask chuck 2400 may be disposed in a process chamber (or an evaporation chamber) 2100.

The process chamber 2100 may have an internal space, and a deposition process for forming a deposition material layer on the backplane substrate 3000 may be performed in the internal space of the process chamber 2100. The process chamber 2100 may be connected to a vacuum pump (not shown), and a vacuum (or substantially low pressure) atmosphere may be created in the internal space of the process chamber 2100 by the vacuum pump. An opening (not shown) for loading/unloading of the backplane substrate 3000 and the deposition mask 4000 may be provided on one wall of the process chamber 2100, and the opening may be opened and closed by a gate valve (not shown).

The deposition source 2200 may be disposed in the process chamber 2100, and a deposition material may be stored in the deposition source 2200. The deposition source 2200 may evaporate a deposition material such as an organic material, an inorganic material, a conductive material, or the like toward the backplane substrate 3000, and the evaporated deposition material may be deposited on the backplane substrate 3000 through the deposition mask 4000. In an embodiment, for example, the deposition source 2200 may evaporate an organic material for forming light emitting layers on the backplane substrate 3000, and may be provided with a heater (not shown) for evaporating the organic material. The above-described evaporated organic material may be deposited on electrode patterns on the backplane substrate 3000 by the deposition mask 4000. In an embodiment, as shown in FIG. 14, the deposition source 2200 may be disposed on the central portion of the bottom surface of the process chamber 2100, but the deposition source 2200 may be configured to move horizontally by a separate driver (not shown).

The substrate chuck 2300 may be disposed above the deposition source 2200 and may support the backplane substrate 3000 such that the backplane substrate 3000 faces the deposition source 2200. In an embodiment, for example, the substrate chuck 2300 may be an electrostatic chuck that holds the rear surface of the backplane substrate 3000 using an electrostatic force. Specifically, the electrode patterns, e.g., first electrodes AND, may be arranged on the front surface of the backplane substrate 3000, and the substrate chuck 2300 may hold the rear surface of the backplane substrate 3000 such that the front surface of the backplane substrate 3000 faces downward, that is, faces the deposition source 2200.

A plurality of lift fingers 2350 for loading the backplane substrate 3000 onto the substrate chuck 2300 may be arranged in the process chamber 2100. The lift fingers 2350 may be arranged around the substrate chuck 2300 and the mask chuck 2400, and may be respectively moved vertically by finger drivers 2360. In an embodiment, for example, three or four lift fingers 2350 may be arranged around the substrate chuck 2300 and the mask chuck 2400.

In an embodiment, the backplane substrate 3000 may be loaded into the process chamber 2100 by a transfer robot (not shown), and may be transferred from the transfer robot onto the lift fingers 2350 under the substrate chuck 2300. In such an embodiment, the rear surface of the backplane substrate 3000 may face the lower surface of the substrate chuck 2300, and the lift fingers 2350 may support the front edge portions of the backplane substrate 3000. The finger drivers 2360 may raise the lift fingers 2350 such that the backplane substrate 3000 becomes adjacent to the lower surface of the substrate chuck 2300, and the rear surface of the backplane substrate 3000 may be held on the lower surface of the substrate chuck 2300 by an electrostatic force.

The finger drivers 2360 may be arranged on the upper lid of the process chamber 2100 and may be respectively connected to the lift fingers 2350 through driving shafts 2362 that extend vertically through the upper lid of the process chamber 2100. The finger drivers 2360 may vertically move the lift fingers 2350 to load or unload the backplane substrate 3000. In addition, the finger drivers 2360 may rotate the lift fingers 2350 with respect to each of the driving shafts 2362. In an embodiment, for example, the finger drivers 2360 may rotate the lift fingers 2350 such that the ends of the lift fingers 2350 do not overlap the substrate chuck 2300 and the mask chuck 2400, thereby enabling vertical movement of the lift fingers 2350. In addition, the finger drivers 2360 may rotate the lift fingers 2350 such that the ends of the lift fingers 2350 overlap the edge portions of the backplane substrate 3000 to support the edge portions of the backplane substrate 3000.

The deposition mask 4000 may be loaded into the process chamber 2100 by the transfer robot, and may be transferred onto the lift fingers 2350 above the mask chuck 2400. The edge portions of the deposition mask 4000 may be placed on the ends of the lift fingers 2350, and the finger drivers 2360 may lower the lift fingers 2350 to load the deposition mask 4000 onto the mask chuck 2400. In such an embodiment, recesses (not shown) into which ends of lift fingers 2350 are inserted may be provided at the edge portions of the top surface of the mask chuck 2400, and the finger drivers 2360 may rotate the lift fingers 2350 such that the lift fingers 2350 do not overlap the mask chuck 2400 after the deposition mask 4000 is loaded on the mask chuck 2400.

The mask chuck 2400 may support the edge portion of the deposition mask 4000. In an embodiment, for example, the mask chuck 2400 may be an electrostatic chuck configured to hold the edge portion of the deposition mask 4000 using an electrostatic force. In an embodiment, the mask chuck 2400 may be provided with a circular opening defined therethrough to expose the deposition mask 4000 toward the deposition source 2200. In an embodiment, for example, the mask chuck 2400 may have a disk shape or a quadrilateral plate shape with a circular opening.

The deposition apparatus 2000 may include a substrate chuck driver 2500 for moving the substrate chuck 2300 and a mask chuck driver 2600 for moving the mask chuck 2400. In an embodiment, for example, the substrate chuck driver 2500 may move the substrate chuck 2300 in the first direction DR1, the second direction DR2, and the third direction DR3 to adjust the position of the backplane substrate 3000. In such an embodiment, the first direction DR1 may be the first horizontal direction, the second direction DR2 may be the second horizontal direction perpendicular to the first direction DR1, and the third direction DR3 may be the vertical direction. That is, the first direction DR1, the second direction DR2, and the third direction DR3 may be the X-axis direction, the Y-axis direction, and the Z-axis direction, respectively.

The substrate chuck driver 2500 may rotate the substrate chuck 2300 around the Z-axis to adjust the azimuth of the backplane substrate 3000. Further, the substrate chuck driver 2500 may rotate the substrate chuck 2300 around the X-axis, and may rotate the substrate chuck 2300 around the Y-axis in order to adjust the inclination of the backplane substrate 3000. In an embodiment, for example, the substrate chuck driver 2500 may include a hexapod actuator 2510 that provides a motion of six degrees of freedom (X, Y, Z, θx, θy, and θz).

The substrate chuck driver 2500 may include a substrate stage 2520 on which the hexapod actuator 2510 is mounted, and a second actuator 2530 connected to the substrate stage 2520. The substrate stage 2520 may be disposed horizontally in the process chamber 2100, and the second actuator 2530 may be disposed above the process chamber 2100. The second actuator 2530 may be connected to the substrate stage 2520 by a plurality of driving shafts 2532 extending in the third direction DR3, i.e., the vertical direction (Z-axis direction) through the upper lid of the process chamber 2100, and may move the substrate stage 2520 in the central axis direction of the hexapod actuator 2510, i.e., the vertical direction. In an embodiment, for example, the second actuator 2530 may be configured using a brushless direct current (DC) motor, a linear motor, a direct drive (DD) motor, or the like, and may adjust the height of the substrate chuck 2300 for loading or unloading the backplane substrate 3000.

The hexapod actuator 2510 may include a first platform connected to the substrate chuck 2300, a second platform mounted on the substrate stage 2520, and six sub-actuators arranged between the first platform and the second platform. In an embodiment, for example, the six sub-actuators may each be configured using a brushless DC motor, a voice coil linear motor, a step motor, a DD motor, a servo motor, or the like, and may move and rotate the first platform to adjust the horizontal position, vertical position, azimuth, and inclination of the backplane substrate 3000.

The mask chuck driver 2600 may move and rotate the mask chuck 2400 to adjust the horizontal position of the deposition mask 4000 and the azimuth of the deposition mask 4000. The mask chuck driver 2600 may move the mask chuck 2400 in a direction parallel to the deposition mask 4000 and rotate the mask chuck 2400 with respect to the central axis of the mask chuck 2400. In an embodiment, for example, the mask chuck driver 2600 may move the mask chuck 2400 in the first direction DR1 (X-axis) and the second direction DR2 (Y-axis), and may rotate the mask chuck 2400 with respect to the third direction DR3 (Z-axis).

The mask chuck driver 2600 may include, e.g., a piezo actuator 2610 that provides a motion of three degrees of freedom (X, Y, and θz). The piezo actuator 2610 may be provided with an opening that communicates with the circular opening of the mask chuck 2400, that is, an opening may be defined in the piezo actuator 2610 to communicate with the circular opening of the mask chuck 2400. The mask chuck 2400 may be spaced upward from the piezo actuator 2610 by a selected distance. In an embodiment, for example, a plurality of support members 2612 may be arranged on the piezo actuator 2610, and the mask chuck 2400 may be disposed on the plurality of support members 2612.

The mask chuck driver 2600 may include a mask stage 2620 that is horizontally disposed in the process chamber 2100 and supports the piezo actuator 2610. In an embodiment, for example, the mask stage 2620 may be provided with an opening that communicates with the opening of the piezo actuator 2610 and may be supported by a plurality of posts 2622 that are connected to the upper lid of the process chamber 2100.

After the backplane substrate 3000 and the deposition mask 4000 are loaded onto the substrate chuck 2300 and the mask chuck 2400, respectively, the second actuator 2530 may lower the substrate chuck 2300 such that the backplane substrate 3000 is brought adjacent to the deposition mask 4000. The hexapod actuator 2510 may adjust the gap between the backplane substrate 3000 and the deposition mask 4000, and may adjust the inclination of the substrate chuck 2300 to adjust the parallelism between the substrate chuck 2300 and the mask chuck 2400. In an embodiment, for example, although not shown, a plurality of gap sensors (not shown) for measuring the gap between the substrate chuck 2300 and the mask chuck 2400 may be mounted at the substrate chuck 2300, and the hexapod actuator 2510 may adjust the parallelism between the substrate chuck 2300 and the mask chuck 2400 based on the measured values of the gap sensors.

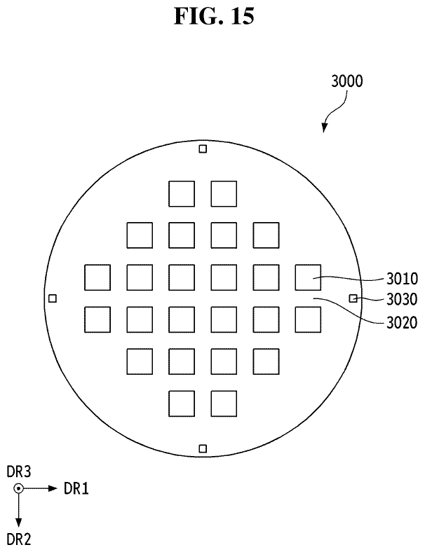

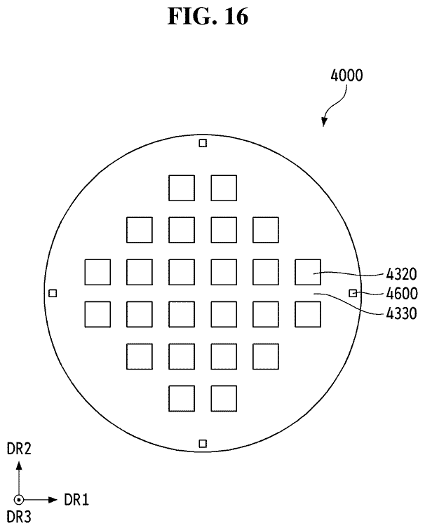

The deposition apparatus 2000 may include cameras 2700 for acquiring positional information of the backplane substrate 3000 and the deposition mask 4000 for alignment between the backplane substrate 3000 and the deposition mask 4000. In an embodiment, for example, substrate alignment keys 3030 (see FIG. 15) may be arranged on the edge portions of the backplane substrate 3000, and mask alignment keys 4600 (see FIG. 16) may be arranged on the edge portions of the deposition mask 4000. The deposition apparatus 2000 may include the cameras 2700 for detecting the substrate alignment keys 3030 and the mask alignment keys 4600, and the substrate chuck driver 2500 or the mask chuck driver 2600 may align the backplane substrate 3000 and the deposition mask 4000 with each other based on the positional information of the substrate alignment keys 3030 and the mask alignment keys 4600 obtained by the cameras 2700.

In an embodiment, as described above, after the parallelism adjustment between the substrate chuck 2300 and the mask chuck 2400 and the positional alignment between the backplane substrate 3000 and the deposition mask 4000 are performed, the backplane substrate 3000 may be positioned on the deposition mask 4000. In an embodiment, for example, the hexapod actuator 2510 may adjust the height of the substrate chuck 2300 such that the gap between the backplane substrate 3000 and the deposition mask 4000 becomes a selected gap, e.g., a gap of several μm. In another embodiment, for example, the hexapod actuator 2510 may adjust the height of the substrate chuck 2300 in a way such that the backplane substrate 3000 is brought into contact with the deposition mask 4000.

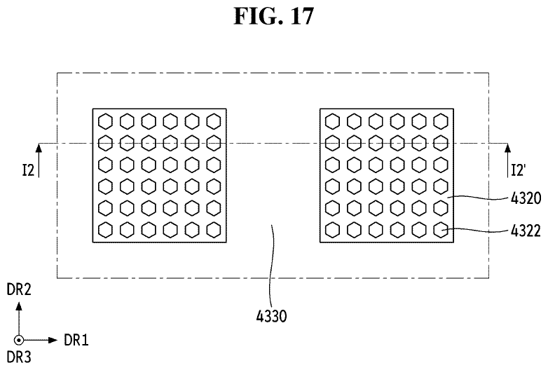

After the backplane substrate 3000 is positioned on the deposition mask 4000, the deposition source 2200 may provide a vapor deposition material onto the backplane substrate 3000 through the deposition mask 4000, thereby forming a deposition material layer on the backplane substrate 3000. In an embodiment, for example, the deposition source 2200 may evaporate an organic material for forming light emitting layers on the backplane substrate 3000, and the evaporated organic material may be deposited on the electrode patterns, e.g., the first electrodes AND of the backplane substrate 3000 through the pixel openings 4312 (see FIG. 17) of the deposition mask 4000.

FIG. 15 is a schematic bottom view illustrating the backplane substrate shown in FIG. 14.

Referring to FIG. 15, an embodiment of the backplane substrate 3000 may include a plurality of display cell regions 3010 and a scribe lane region 3020 disposed between the display cell regions 3010. The display cell regions 3010 may be arranged in a matrix form along the first direction DR1 and the second direction DR2 as illustrated in FIG. 15, and may be individualized into display panels 100 (see FIG. 3) by a dicing process after the display manufacturing process is completed. In an embodiment, for example, the first direction DR1 may be a first horizontal direction, and the second direction DR2 may be a second horizontal direction perpendicular to the first direction DR1. In addition, each of the display cell regions 3010 may have, for example, a quadrilateral shape as shown in the drawing.

In an embodiment, for example, each of the display cell regions 3010 may include the semiconductor backplane SBP, the light emitting element backplane EBP disposed on the semiconductor backplane SBP, the reflective electrode layer RL disposed on the light emitting element backplane EBP, and the insulating films INS10 and INS11 disposed on the reflective electrode layer RL as shown in FIG. 9. In addition, each of the display cell regions 3010 may include the plurality of electrode patterns, for example, the plurality of first electrodes AND arranged on the insulating film INS11, and the first electrodes AND may be connected to the reflective electrode layer RL through the plurality of vias VA10. In this case, the electrode patterns of the display cell regions 3010 may be arranged on the front surface of the backplane substrate 3000, and the substrate chuck 2300 may hold the rear surface of the backplane substrate 3000 such that the electrode patterns of the display cell regions 3010 face downward, i.e., face the deposition source 2200.

The substrate alignment keys 3030 may be arranged on the edge portions of the backplane substrate 3000 for alignment with the deposition mask 4000. As illustrated, four substrate alignment keys 3030 are arranged on the backplane substrate 3000, but the number of substrate alignment keys 3030 may be variously changed, and thus, the scope of the present disclosure is not limited by the number of substrate alignment keys 3030.

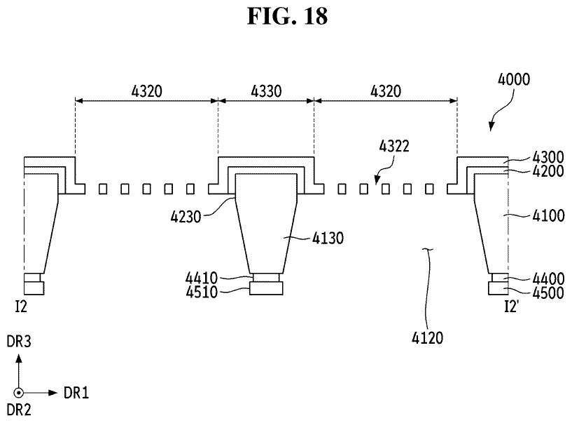

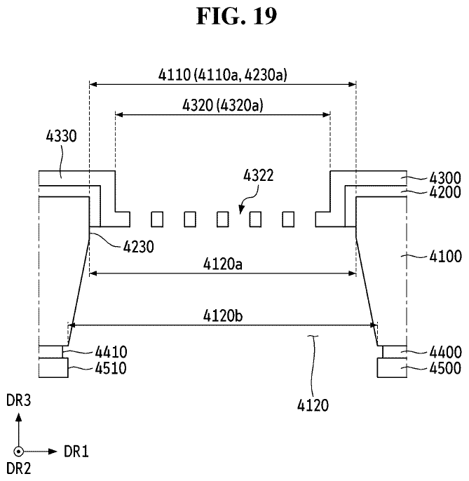

FIG. 16 is a schematic plan view illustrating the deposition mask shown in FIG. 14. FIG. 17 is a schematic plan view illustrating the mask cell regions shown in FIG. 16. FIG. 18 is a schematic cross-sectional view taken along line I2-I2′ shown in FIG. 17. FIG. 19 is an enlarged cross-sectional view schematically illustrating the mask cell region, intermediate opening, and cell opening shown in FIG. 18.

Referring to FIGS. 16 to 19, an embodiment of the deposition mask 4000 may include mask cell regions 4320 respectively corresponding to the display cell regions 3010 of the backplane substrate 3000. Each of the mask cell regions 4320 may be provided with a plurality of pixel openings 4322 defined therethrough to expose electrode patterns, e.g., the first electrodes AND, of the backplane substrate 3000 in a deposition process.

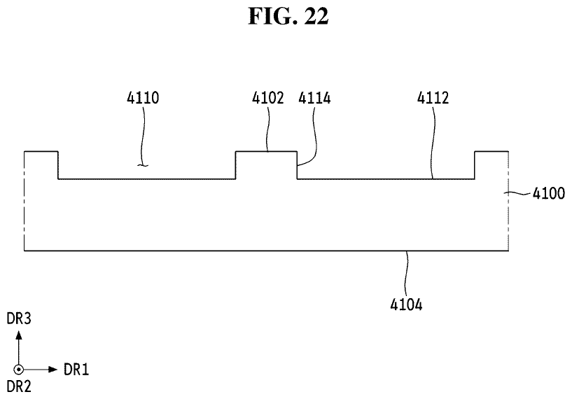

In an embodiment, for example, the deposition mask 4000 may include a mask substrate 4100, an intermediate inorganic film 4200 disposed on a front surface 4102 (see FIG. 22) of the mask substrate 4100, and a membrane 4300 disposed on the intermediate inorganic film 4200. In such an embodiment, the membrane 4300 may include a plurality of mask cell regions 4320, and each of the mask cell regions 4320 may be provided with a plurality of pixel openings 4322. Additionally, the membrane 4300 may include a grid region 4330 disposed between the mask cell regions 4320, and the grid region 4330 may correspond to the scribe lane region 3020 of the backplane substrate 3000.

According to an embodiment of the present disclosure, the mask substrate 4100 may be provided with upper openings corresponding to recesses 4110 (see FIG. 22) formed in the front surface portions and cell openings 4120 respectively connected to the upper openings corresponding to the recesses 4110. The cell openings 4120 may penetrate the mask substrate 4100 and be connected to the recesses 4110 shown in FIG. 22 such that the upper openings corresponding to the recesses 4110 are formed. That is, the cell openings 4120 may be formed to penetrate the bottom portions of the recesses 4110 shown in FIG. 22. In such an embodiment, the mask cell regions 4320 of the membrane 4300 may be arranged in the upper openings corresponding to the recesses 4110, respectively, and the grid region 4330 may be disposed on the front surface 4102 of the mask substrate 4100. Additionally, the mask substrate 4100 may include a rib region 4130 defining the cell openings 4120.

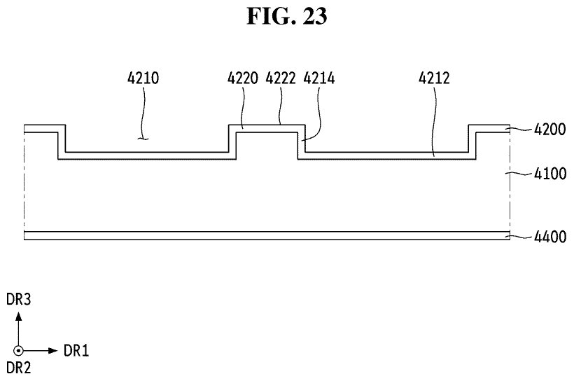

The intermediate inorganic film 4200 may be provided with intermediate openings 4230 connecting the mask cell regions 4320 and the cell openings 4120 in a way such that the mask cell regions 4320 are exposed through the cell openings 4120. That is, the pixel openings 4322 may communicate with the cell openings 4120 by the intermediate openings 4230 of the intermediate inorganic film 4200. Additionally, the pixel openings 4322 may be defined or formed to penetrate (or through) the mask cell regions 4320 and be exposed toward the deposition source 2200 through the intermediate openings 4230 and the cell openings 4120. In such an embodiment, the grid region 4330 of the membrane 4300 may be disposed on a portion 4220 (see FIG. 23) of the intermediate inorganic film 4200 disposed on the front surface 4102 of the mask substrate 4100.

As a result, in the deposition process using the deposition mask 4000, the mask cell regions 4320 of the membrane 4300 may be positioned lower than the grid region 4330 of the membrane 4300, and thus, the mask cell regions 4320 of the membrane 4300 may be effectively prevented from coming into contact with the backplane substrate 3000. Additionally, damage to the mask cell regions 4320 due to contact with the backplane substrate 3000 or foreign matters between the backplane substrate 3000 and the deposition mask 4000 may be effectively prevented or substantially reduced. That is, while the deposition process is performed as described above, the grid region 4330 of the membrane 4300 may function as a spacer between the mask cell regions 4320 of the membrane 4300 and the backplane substrate 3000.

The mask cell regions 4320 may be arranged in a matrix form along the first direction DR1 and the second direction DR2, as illustrated in FIG. 16. In an embodiment, for example, the first direction DR1 may be the first horizontal direction, and the second direction DR2 may be the second horizontal direction perpendicular to the first horizontal direction. In such an embodiment, the mask cell regions 4320 may be arranged to respectively correspond to the display cell regions 3010 of the backplane substrate 3000, and each of the mask cell regions 4320 may have a quadrilateral shape as shown in one example.

A second intermediate inorganic film 4400 and a rear inorganic film 4500 may be disposed on a rear surface 4104 (see FIG. 22) of the mask substrate 4100. In an embodiment, for example, the second intermediate inorganic film 4400 may be disposed on the rear surface 4104 of the mask substrate 4100, and the rear inorganic film 4500 may be disposed on the second intermediate inorganic film 4400. The second intermediate inorganic film 4400 and the rear inorganic film 4500 may be provided with second intermediate openings 4410 and rear openings 4510 respectively communicating with the cell openings 4120, respectively, and the rear inorganic film 4500 may function as an etching mask in an etching process for forming the cell openings 4120. In this case, the mask cell regions 4320 may be exposed toward the deposition source 2200 through the intermediate openings 4230, the cell openings 4120, the second intermediate openings 4410, and the rear openings 4510, and while the deposition process is performed, the vapor deposition material may be provided onto the backplane substrate 3000 through the rear openings 4510, the second intermediate openings 4410, the cell openings 4120, the intermediate openings 4230, and the pixel openings 4322.

In an embodiment, for example, the intermediate inorganic film 4200 may include a same material as the second intermediate inorganic film 4400, and the membrane 4300 may include a same material as the rear inorganic film 4500. In such an embodiment, the membrane 4300 may include a material having etching selectivity with respect to the intermediate inorganic film 4200 and the mask substrate 4100. In an embodiment, for example, the mask substrate 4100 may include silicon (Si), the intermediate inorganic film 4200 and the second intermediate inorganic film 4400 may include silicon oxide (SiOx), and the membrane 4300 and the rear inorganic film 4500 may include silicon nitride (SiNx). In such an embodiment, the intermediate inorganic film 4200 and the second intermediate inorganic film 4400 may be simultaneously formed through a thermal oxidation process, and the membrane 4300 and the rear inorganic film 4500 may be simultaneously formed through a chemical vapor deposition (CVD) process.

The pixel openings 4322 of the membrane 4300 may be formed by an anisotropic etching process, e.g., a reactive ion etching (RIE) process. In an embodiment, for example, after forming, on the membrane 4300, a photoresist pattern exposing the portions where the pixel openings 4322 are to be formed, the RIE process using the photoresist pattern as an etching mask may be performed to form the pixel openings 4322 that expose the intermediate inorganic film 4200. In such an embodiment, the pixel openings 4322 may be formed to penetrate the membrane 4300, and the intermediate inorganic film 4200 may function as an etch stop film in the RIE process.

The second intermediate openings 4410 and the rear openings 4510 may be formed by an anisotropic etching process, e.g., an RIE process. In an embodiment, for example, after forming, on the rear inorganic film 4500, a photoresist pattern that exposes portions where the rear openings 4510 are to be formed, an RIE process that uses the photoresist pattern as an etching mask may be performed to form the second intermediate openings 4410 and the rear openings 4510 that expose the rear portions of the mask substrate 4100.

The cell openings 4120 of the mask substrate 4100 may be formed to expose the intermediate inorganic film 4200 through an anisotropic etching process using the rear inorganic film 4500 and the second intermediate inorganic film 4400 as an etching mask. In an embodiment, for example, a single crystal silicon substrate may be used as the mask substrate 4100, and the cell openings 4120 may be formed by a first wet etching process using a first etchant such as a tetramethylammonium hydroxide (TMAH) solution, or a potassium hydroxide (KOH) solution. In this case, the <100> crystal direction of the single crystal silicon substrate used as the mask substrate 4100 may be the third direction DR3 perpendicular to the first direction DR1 and the second direction DR2, and accordingly, the cell openings 4120 may be formed to have a width that gradually decreases from the rear surface of the mask substrate 4100 toward the front surface of the mask substrate 4100 through the first wet etching process. In an embodiment, for example, the inner side surfaces of the cell openings 4120 may have an inclination of about 54.74° with respect to the rear surface of the mask substrate 4100. Further, as illustrated in FIG. 19, the cell openings 4120 may have a first width 4120a adjacent to the front surface 4102 of the mask substrate 4100 and a second width 4120b adjacent to the rear surface 4104 of the mask substrate 4100. The first width 4120a of the cell openings 4120 may be less than the second width 4120b of the cell openings 4120.

In another embodiment, for example, the cell openings 4120 of the mask substrate 4100 may be formed by a deep reactive ion etching (DRIE) process or a cryogenic etching process. In such an embodiment, the first width 4120a and the second width 4120b of the cell openings 4120 may be equal to each other.

According to an embodiment of the present disclosure, the cell openings 4120 of the mask substrate 4100 may be respectively connected to the upper openings corresponding to the recesses 4110. In such an embodiment, the recesses 4110 may be sufficiently opened by the cell openings 4120 such that the upper openings corresponding to the recesses 4110 may be formed. In an embodiment, for example, as shown in FIG. 19, the first width 4120a of the cell openings 4120 may be equal to a width 4110a of the upper openings corresponding to the recesses 4110.

The intermediate openings 4230 of the intermediate inorganic film 4200 may be formed through a wet etching process after forming the cell openings 4120 of the mask substrate 4100. In an embodiment, for example, when the intermediate inorganic film 4200 includes silicon oxide (SiOx), the intermediate openings 4230 may be formed by a second wet etching process that uses a second etchant such as buffered oxide etchant (BOE) or diluted hydrofluoric acid (diluted HF). As a result, the pixel openings 4322 of the membrane 4300 may communicate with the cell openings 4120 of the mask substrate 4100 through the intermediate openings 4230 of the intermediate inorganic film 4200.

In another embodiment, for example, the second intermediate inorganic film 4400 may be omitted. In such an embodiment, the rear inorganic film 4500 may be disposed on the rear surface 4104 of the mask substrate 4100, and the intermediate inorganic film 4200 may be formed through a CVD process. In addition, the rear inorganic film 4500 may be formed separately from the membrane 4300 through a CVD process and may include a material different from the membrane 4300. In another embodiment, for example, both the intermediate inorganic film 4200 and the second intermediate inorganic film 4400 may be omitted. In such an embodiment, the membrane 4300 may be formed on the front surface 4102 of the mask substrate 4100, and the rear inorganic film 4500 may be formed on the rear surface 4104 of the mask substrate 4100. In addition, the membrane 4300 and the rear inorganic film 4500 may be formed simultaneously or separately.

The deposition mask 4000 may include the mask alignment keys 4600 for alignment with the backplane substrate 3000. In an embodiment, for example, the mask alignment keys 4600 may be arranged on edge portions of the deposition mask 4000 to correspond with the substrate alignment keys 3030 of the backplane substrate 3000. In an embodiment, as shown in FIG. 16, the deposition mask 4000 may include four mask alignment keys 4600, but the number of the mask alignment keys 4600 may be variously changed, and thus the scope of the present disclosure is not limited by the number of the mask alignment keys 4600.

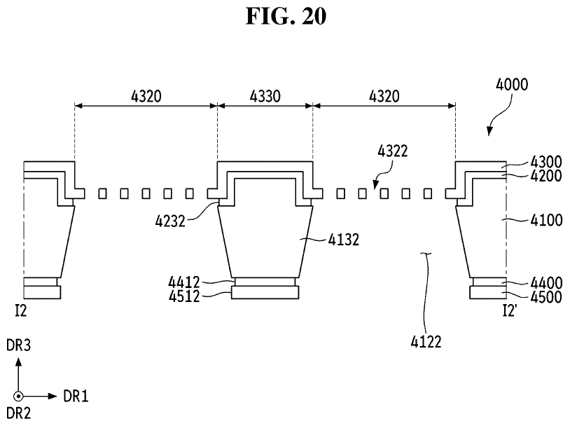

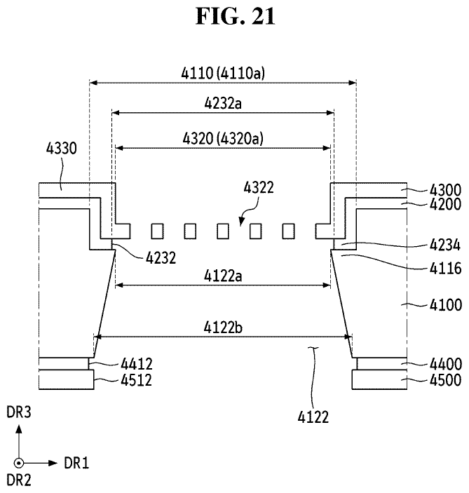

FIG. 20 is a schematic cross-sectional view illustrating a deposition mask according to another embodiment of the present disclosure. FIG. 21 is a schematic enlarged cross-sectional view illustrating the mask cell region, intermediate opening, and cell opening shown in FIG. 20.

Referring to FIGS. 20 and 21, according to another embodiment of the present disclosure, the deposition mask 4000 may include the mask substrate 4100, the intermediate inorganic film 4200 disposed on the front surface 4102 of the mask substrate 4100, the membrane 4300 disposed on the intermediate inorganic film 4200, the second intermediate inorganic film 4400 disposed on the rear surface 4104 of the mask substrate 4100, and the rear inorganic film 4500 disposed on the second intermediate inorganic film 4400. The mask substrate 4100 may be provided with cell openings 4122, and may include a rib region 4132 defining the cell openings 4122. The membrane 4300 may include mask cell regions 4320, and may be provided with pixel openings 4322 penetrating (defined or formed through) the mask cell regions 4320. The intermediate inorganic film 4200 may be provided with intermediate openings 4232 serving to connect the cell openings 4122 to the pixel openings 4322. The second intermediate inorganic film 4400 and the rear inorganic film 4500 may respectively be provided with second intermediate openings 4412 and rear openings 4512 that communicate with the cell openings 4122.

The cell openings 4122 of the mask substrate 4100 may be connected to the upper openings corresponding to the recesses 4110, respectively. In such an embodiment, the cell openings 4122 of the mask substrate 4100 may communicate with the rear openings 4512 of the rear inorganic film 4500 and the second intermediate openings 4412 of the second intermediate inorganic film 4400, and may be formed through the first wet etching process using the rear inorganic film 4500 as an etching mask. In such an embodiment, bottom surfaces (or recessed front surfaces) 4112 defining the recesses 4110 may each be partially opened by the cell openings 4122. In such an embodiment, each of the cell openings 4122 may have a first width 4122a adjacent to the front surface 4102 of the mask substrate 4100 and a second width 4122b adjacent to the rear surface 4104 of the mask substrate 4100. The first width 4122a of the cell openings 4122 may be less than the width 4122b of the upper openings corresponding to the recesses 4110. In addition, the first wet etching process may form a bottom edge portion 4116 defining an upper opening corresponding to the recess 4110 having a ring shape, for example, a quadrangular ring shape. That is, the ring-shaped stepped portions 4116 respectively surrounding the cell openings 4122 may be formed through the first wet etching process. In such an embodiment, the upper openings defined by the ring-shaped stepped portions may be referred to as recessed openings.

Portions of the intermediate inorganic film 4200 exposed by the cell openings 4122, that is, portions of the intermediate inorganic film 4200 formed on the bottom surfaces 4112 of the recesses 4110, may be partially removed by the second wet etching process using the second etchant, thereby forming the intermediate openings 4232 that serve to connect the pixel openings 4322 to the cell openings 4122. In this case, a width 4232a of the intermediate openings 4232 may be greater than the first width 4122a of the cell openings 4122.

According to an embodiment, after the intermediate openings 4232 are formed, portions 4234 of the intermediate inorganic film 4200 having a ring shape, for example, a quadrangular ring shape may remain on the bottom edge portions 4116 of the recesses 4110, that is, the stepped portions 4116 of the mask substrate 4100. That is, the ring-shaped inorganic patterns 4234 surrounding the intermediate openings 4232 may be formed on the stepped portions 4116 of the mask substrate 4100 by the second wet etching process, and the intermediate openings 4232 may be defined by the ring-shaped inorganic patterns 4234. In this case, the mask cell regions 4320 of the membrane 4300 may be supported by the ring-shaped portions 4234 of the intermediate inorganic film 4200 and the bottom edge portions 4116 of the upper openings corresponding to the recesses 4110. That is, the ring-shaped portions 4234 of the intermediate inorganic film 4200 and the bottom edge portions 4116 of the upper openings corresponding to the recesses 4110 may function as support members supporting the mask cell regions 4320. Accordingly, the rigidity of the mask cell regions 4320 may be improved, and warpage of the mask cell regions 4320 may be reduced.

FIGS. 22 to 28 are schematic cross-sectional views illustrating a method of manufacturing a deposition mask according to an embodiment of the present disclosure.

Referring to FIG. 22, in an embodiment of a method of manufacturing a deposition mask, the recesses 4110 may be formed in front surface portions of the mask substrate 4100. In an embodiment, for example, the mask substrate 4100 may include single crystal silicon. In an embodiment, for example, a single crystal silicon substrate having a thickness in a range of about 700 micrometers (μm) to about 800 μm, e.g., about 775 μm, may be used as the mask substrate 4100.

Specifically, after forming a first photoresist pattern (not shown) on the front surface 4102 of the mask substrate 4100, an anisotropic etching process, for example, an RIE process using the first photoresist pattern as an etching mask is performed so that the recesses 4110 may be formed in the front surface portions of the mask substrate 4100, respectively. The first photoresist pattern may be provided with openings that expose the front surface portions of the mask substrate 4100 corresponding to the display cell regions 3010 of the backplane substrate 3000, and the front surface portions of the mask substrate 4100 exposed by the openings may be removed. In an embodiment, for example, each of the recesses 4110 may be defined by the bottom surface 4112 having an approximately quadrilateral shape and may be formed to have a depth in a range of about 1 μm to about 5 μm. In an embodiment, for example, the recesses 4110 may be formed through an RIE process using a reactive gas such as SF₆, SF₆/O₂, and CHF₃/O₂, a sputtering gas such as Ar and O₂/Ar, and a source gas for forming a protective film, such as CF₄, C₄F₆, and C₄F₈. The first photoresist pattern may be removed by an ashing and/or stripping process after the recesses 4110 are formed.

Referring to FIG. 23, in an embodiment of a method of manufacturing a deposition mask, the intermediate inorganic film 4200 may be formed on the front surface 4102 of the mask substrate 4100 and the inner surfaces of the recess 4110. In an embodiment, the intermediate inorganic film 4200 may be conformally formed to have a uniform thickness on the front surface 4102 of the mask substrate 4100, the bottom surfaces 4112 of the recesses 4110 (i.e., the bottom surfaces 4112 defining the recesses 4110), and inner side surfaces 4114 (see FIG. 22) of the recesses 4110 (i.e., the inner side surfaces 4114 defining the recesses 4110). In an embodiment, for example, the intermediate inorganic film 4200 may include silicon oxide (SiOx), and may be formed to have a thickness in a range of about 0.5 μm to 2 μm through a thermal oxidation process. In particular, second recesses 4210 defined by the intermediate inorganic film 4200 may be formed in the recesses 4110, respectively. Specifically, the intermediate inorganic film 4200 may include portions 4212 of the intermediate inorganic film 4200 formed on (or formed to cover) the bottom surfaces 4112 of the recesses 4110, portions 4214 of the intermediate inorganic film 4200 formed on (or formed to cover) the inner side surfaces 4114 of the recesses 4110, and the portion 4220 of the intermediate inorganic film 4200 formed on (or formed to cover) the front surface 4102 of the mask substrate 4100. Each of the second recesses 4210 may be defined by the portion 4212 of the intermediate inorganic film 4200 formed on the bottom surface 4112 of the recess 4110 and the portions 4214 of the intermediate inorganic film 4200 formed on the inner side surfaces 4114 of the recess 4110.

The second intermediate inorganic film 4400 may be formed on (or formed to cover) the rear surface 4104 (see FIG. 22) of the mask substrate 4100. In an embodiment, for example, the second intermediate inorganic film 4400 may be formed simultaneously with the intermediate inorganic film 4200 through a thermal oxidation process. Accordingly, the second intermediate inorganic film 4400 may include a same material as the intermediate inorganic film 4200 and may have a same thickness as the intermediate inorganic film 4200.

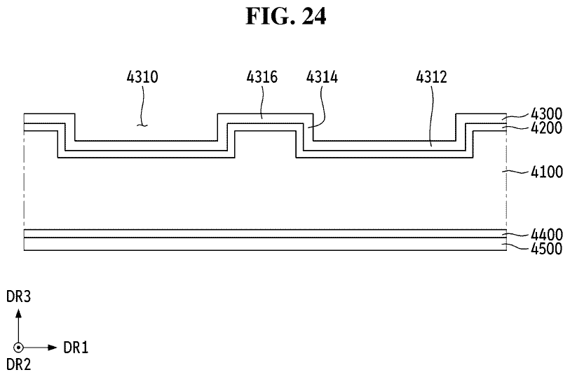

Referring to FIG. 24, in an embodiment of a method of manufacturing a deposition mask, the membrane 4300 may be formed on the intermediate inorganic film 4200. Specifically, the membrane 4300 may be formed conformally on a top surface 4222 (see FIG. 23) of the intermediate inorganic film 4200, the bottom surfaces of the second recesses 4210, and the inner side surfaces of the second recesses 4210 with a uniform thickness. In an embodiment, for example, the membrane 4300 may contain silicon nitride (SiNx) and may be formed by a CVD process. In an embodiment, for example, a silicon source gas, such as monosilane (SiH₄), disilane (Si₂H₆), or dichlorosilane (DCS) (SiH₂Cl₂), and a nitrogen source gas, such as N₂ or NH₃, may be supplied onto the intermediate inorganic film 4200, and the membrane 4300 may be formed with a thickness in a range of about 0.5 μm to about 3 μm by a reaction between the silicon source gas and the nitrogen source gas.

In particular, third recesses 4310 defined by the membrane 4300 may be formed in the second recesses 4210, respectively. Specifically, each of the third recesses 4310 may be defined by the portion 4312 of the membrane 4300 formed on (or formed to cover) the bottom surface of the second recess 4210 and the portion 4314 of the membrane 4300 formed on the inner side surface of the second recess 4210. In this case, the portions of the membrane 4300 formed above the bottom surfaces of the recesses 4110, that is, the portions 4312 of the membrane 4300 formed on the bottom surfaces of the second recesses 4210, may be used as the mask cell regions 4320 (see FIG. 18) of the deposition mask 4000. Therefore, each of the mask cell regions 4320 may be defined by the portion 4314 of the membrane 4300 formed on the inner side surface of the second recess 4210, that is, the inner side surface of the third recess 4310. In addition, a portion 4316 of the membrane 4300 formed above the front surface 4102 of the mask substrate 4100, that is, the portion 4316 of the membrane 4300 formed on (or formed to cover) the top surface 4222 of the intermediate inorganic film 4200 may be used as the grid region 4330 (see FIG. 18) of the deposition mask 4000.

The rear inorganic film 4500 may be formed on (or formed to cover) the second intermediate inorganic film 4400. In an embodiment, for example, the rear inorganic film 4500 may include silicon nitride (SiNx) and may be formed by a CVD process. In an embodiment, for example, the membrane 4300 and the rear inorganic film 4500 may be formed simultaneously by a CVD process. Accordingly, the rear inorganic film 4500 may include the same material as the membrane 4300 and may have the same thickness as the membrane 4300.

In another embodiment, for example, the second intermediate inorganic film 4400 may be omitted. In such an embodiment, the rear inorganic film 4500 may be formed on the rear surface 4104 of the mask substrate 4100, and the intermediate inorganic film 4200 may be formed through a CVD process. Further, the rear inorganic film 4500 may be formed through a CVD process separately from the membrane 4300 and may include a material different from the membrane 4300. In another embodiment, for example, both the intermediate inorganic film 4200 and the second intermediate inorganic film 4400 may be omitted. In such an embodiment, the membrane 4300 may be formed on the front surface 4102 of the mask substrate 4100, and the rear inorganic film 4500 may be formed on the rear surface 4104 of the mask substrate 4100. Further, the membrane 4300 and the rear inorganic film 4500 may be formed simultaneously or separately.

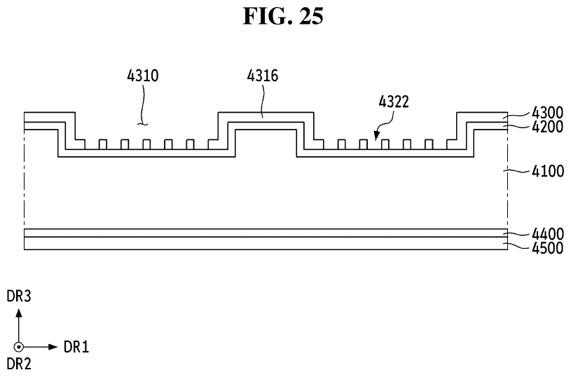

Referring to FIG. 25, in an embodiment of a method of manufacturing a deposition mask, the pixel openings 4322 may be formed by patterning the membrane 4300. In an embodiment, for example, the pixel openings 4322 may be formed by forming, on the membrane 4300, a second photoresist pattern (not shown) that exposes the portions where the pixel openings 4322 are to be formed and then performing an anisotropic etching process, for example, an RIE process, using the second photoresist pattern as an etching mask. In particular, the pixel openings 4322 may be formed to penetrate the membrane 4300, that is, to expose the intermediate inorganic film 4200. Specifically, the pixel openings 4322 may be formed to penetrate the portions 4312 of the membrane 4300 formed on the bottom surfaces of the second recesses 4210. Thus, the portions 4212 of the intermediate inorganic film 4200 formed on the bottom surfaces 4112 of the recesses 4110 may be exposed by the pixel openings 4322.

In an embodiment, for example, the RIE process may be performed using a first reaction gas containing fluorine, such as CF₄, C₂F₄, C₂F₆, C₃F₆, C₃F₈, C₄F₆, C₄F₈, CH₃F, CH₂F₂, C₂HF₅, CHF₃, NF₃, SF₆, or the like, a second reaction gas containing oxygen, such as O₂, NO, NO₂, or the like, and a sputtering gas, such as He, Ne, Ar, Xe, or the like. The second photoresist pattern may be removed by an ashing and/or strip process after the pixel openings 4322 are formed.

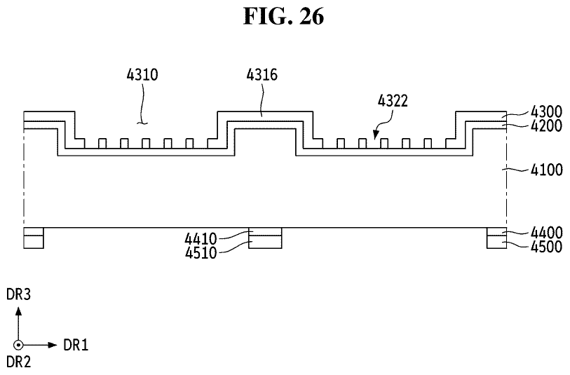

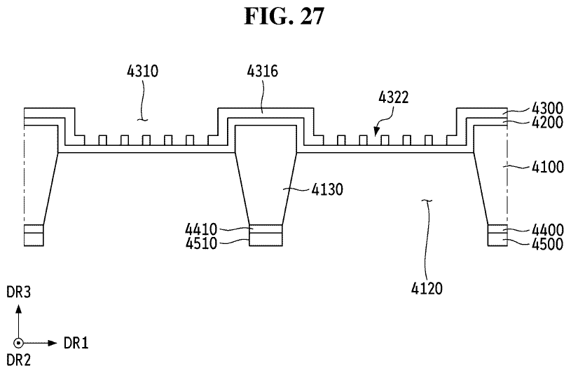

Referring to FIGS. 26 and 27, in an embodiment of a method of manufacturing a deposition mask, the mask substrate 4100 may be patterned to form the cell openings 4120. In an embodiment, for example, after forming the rear openings 4510 and the second intermediate openings 4410 that expose the rear portions of the mask substrate 4100 where the cell openings 4120 are to be formed, an etching process using the rear inorganic film 4500 and the second intermediate inorganic film 4400 as an etching mask may be performed, thereby forming the cell openings 4120.

In an embodiment, for example, a third photoresist pattern (not shown) may be formed on the rear inorganic film 4500 to expose the portions where the rear openings 4510 are to be formed. Then, an anisotropic etching process, for example, an RIE process using the third photoresist pattern as an etching mask may be performed. The above RIE process may be performed until the rear portions of the mask substrate 4100 are exposed, and thus the rear openings 4510 and the second intermediate openings 4410 respectively penetrating the rear inorganic film 4500 and the second intermediate inorganic film 4400 may be formed as illustrated in FIG. 26. The third photoresist pattern may be removed by an ashing and/or stripping process after the rear openings 4510 and the second intermediate openings 4410 are formed.

The cell openings 4120 may be formed by the first wet etching process using the second intermediate inorganic film 4400 and the rear inorganic film 4500 as an etching mask. In an embodiment, for example, as illustrated in FIG. 27, the mask substrate 4100 may be partially removed to expose the intermediate inorganic film 4200 through the first wet etching process using the second intermediate inorganic film 4400 and the rear inorganic film 4500 as an etching mask, thereby forming the cell openings 4120 penetrating the mask substrate 4100 and the rib region 4130 defining the cell openings. In an embodiment, for example, the first wet etching process for forming the cell openings 4120 may be performed using the first etchant such as a TMAH solution or a KOH solution. In this case, the <100> crystal direction of the single crystal silicon substrate used as the mask substrate 4100 may be the third direction DR3, and accordingly, the cell openings 4120 may be formed to have a width that gradually decreases from the rear surface of the mask substrate 4100 toward the front surface of the mask substrate 4100. In an embodiment, for example, the inner side surfaces of the cell openings 4120 may be formed to have an inclination of approximately 54.74° with respect to the rear surface of the mask substrate 4100. In an embodiment, as shown in FIG. 19, the first width 4120a of the cell openings 4120 adjacent to the front surface 4102 of the mask substrate 4100 may be less than the second width 4120b of the cell openings 4120 adjacent to the rear surface 4104 of the mask substrate 4100.

In another embodiment, for example, the cell openings 4120 of the mask substrate 4100 may be formed by a deep reactive ion etching (DRIE) process or a cryogenic etching process. In such an embodiment, the first width 4120a and the second width 4120b of the cell openings 4120 may be made equal to each other.

According to an embodiment, the cell openings 4120 of the mask substrate 4100 may be connected to the recesses 4110, respectively. That is, the cell openings 4120 may expose the portions 4212 of the intermediate inorganic film 4200 formed on the bottom surfaces 4112 of the recesses 4110. In an embodiment, for example, the recesses 4110 may be fully opened by the cell openings 4120, thereby defining the upper openings corresponding to the recesses 4110. That is, the bottom portion of each recess 4110 may be completely removed by the cell opening 4120. In an embodiment, for example, as shown in FIG. 19, the first width 4120a of the cell openings 4120 may be equal to a width 4110a of the recesses 4110. As a result, the inner side surfaces of the mask substrate 4100 defining the cell openings 4120 may be directly connected to the inner side surfaces 4114 of the mask substrate 4100 defining the upper openings corresponding to the recesses 4110.

In some embodiments, in the first wet etching process to form the cell openings 4120, the intermediate inorganic film 4200 may function as an etch stop film. Specifically, in a case where the intermediate inorganic film 4200 is omitted, the first etchant may be provided on the bottom surfaces 4112 of the recesses 4110 through the pixel openings 4322, and hydrogen (H₂) bubbles may be generated in the pixel openings 4322 due to the reaction between the first etchant and the mask substrate 4100. In this case, the mask cell regions 4320 of the membrane 4300 may be damaged by the hydrogen bubbles. The intermediate inorganic film 4200 may be used to effectively prevent the first etchant from being provided onto the bottom surfaces 4112 of the recesses 4110 through the pixel openings 4322, thereby preventing or reducing damage to the mask cell regions 4320.

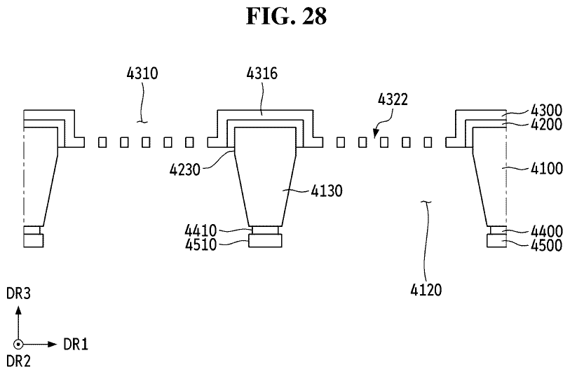

Referring to FIG. 28, the intermediate inorganic film 4200 may be patterned to form the intermediate openings 4230 serving to connect the pixel openings 4322 to the cell openings 4120. The intermediate openings 4230 may be formed by a wet etching process. In an embodiment, for example, where the intermediate inorganic film 4200 includes silicon oxide (SiOx), the intermediate openings 4230 may be formed by a second wet etching process using a second etchant such as BOE or diluted HF. That is, the portions 4212 of the intermediate inorganic film 4200 exposed by the cell openings 4120 may be removed by the second etchant, thereby forming the intermediate openings 4230 that serve to connect the pixel openings 4322 to the cell openings 4120.

The intermediate openings 4230 may be formed in a way such that the mask cell regions 4320 of the membrane 4300, that is, the portions 4312 of the membrane 4300 formed on the bottom surfaces of the second recesses 4210, are exposed through the cell openings 4120. According to an embodiment, the second wet etching process may be performed to sufficiently remove the portions 4212 of the intermediate inorganic film 4200 formed on the bottom surfaces 4112 of the recesses 4110, that is, to partially expose the inner side surfaces 4114 of the recesses 4110. Accordingly, as shown in FIG. 19, a width 4230a of the intermediate openings 4230 may be equal to the first width 4120a of the cell openings 4120 and the width 4110a of the recesses 4110. That is, the intermediate openings 4230 may be defined by the inner side surfaces 4114 of the cell openings 4120. In addition, the first width 4120a and the second width 4120b of the cell openings 4120 may be greater than a width 4320a of the mask cell regions 4320, that is, the width of the third recess 4310. Accordingly, in the deposition process using the deposition mask 4000, the amount of deposition material blocked by the rear inorganic film 4500 may be reduced.

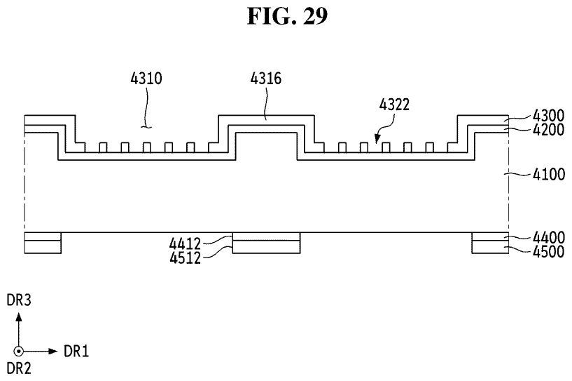

FIGS. 29 to 31 are schematic cross-sectional views illustrating a method of manufacturing a deposition mask according to another embodiment of the present disclosure.

Referring to FIGS. 22 to 25 and FIG. 29, in an embodiment of a method of manufacturing a deposition mask, the recesses 4110 may be formed in front surface portions of the mask substrate 4100. The intermediate inorganic film 4200 may be formed on the front surface 4102 of the mask substrate 4100 and the inner surfaces of the recesses 4110, and the second intermediate inorganic film 4400 may be formed on the rear surface 4104 of the mask substrate 4100. The membrane 4300 may be formed on the top surface 4222 of the intermediate inorganic film 4200 and the inner surfaces of the second recesses 4210, and the rear inorganic film 4500 may be formed on the second intermediate inorganic film 4400. The membrane 4300 may be patterned to form the pixel openings 4322 exposing the intermediate inorganic film 4200. Since processes of forming the recesses 4110, the intermediate inorganic film 4200, the second intermediate inorganic film 4400, the membrane 4300, the rear inorganic film 4500, and the pixel openings 4322 are substantially the same as those described above with reference to FIGS. 22 to 25, any repetitive detailed description thereof will be omitted.

After forming the pixel openings 4322, the second intermediate openings 4412 and the rear openings 4512 that expose the rear portions of the mask substrate 4100 may be formed as shown in FIG. 29. Since a process of forming the second intermediate openings 4412 and the rear openings 4512 is substantially the same as that described above with reference to FIG. 26, any repetitive detailed description thereof will be omitted.

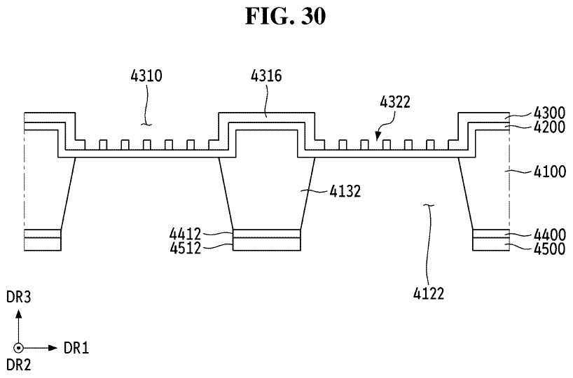

Referring to FIG. 30, in an embodiment of a method of manufacturing a deposition mask, the cell openings 4122 exposing the intermediate inorganic film 4200 and the rib region 4132 defining the cell openings 4122 may be formed by patterning the mask substrate 4100. The cell openings 4122 may be formed by a wet etching process. In an embodiment, for example, the cell openings 4122 may be formed by a first wet etching process using a first etchant such as a TMAH solution or a KOH solution. Since the process of forming the cell openings 4122 is substantially the same as that described above with reference to FIG. 27, any repetitive detailed description thereof will be omitted.

In such an embodiment, the cell openings 4122 of the mask substrate 4100 may be connected to the recesses 4110, respectively. In particular, the cell openings 4122 may partially expose the portions 4212 of the intermediate inorganic film 4200 formed on the bottom surfaces 4112 of the recesses 4110. That is, the bottom surfaces 4112 of the recesses 4110 may be partially opened by the cell openings 4122. In an embodiment, for example, as shown in FIG. 21, the first width 4122a of the cell openings 4122 may be equal to or greater than the width 4320a of the mask cell regions 4320. In addition, the first width 4122a of the cell openings 4122 may be less than the width 4110a of the recesses 4110. The bottom edge portion 4116 of the recess 4110 having a ring shape, for example, a quadrangular ring shape may be formed through the first wet etching process. That is, the ring-shaped stepped portions 4116 respectively surrounding the cell openings 4122 may be formed through the first wet etching process.

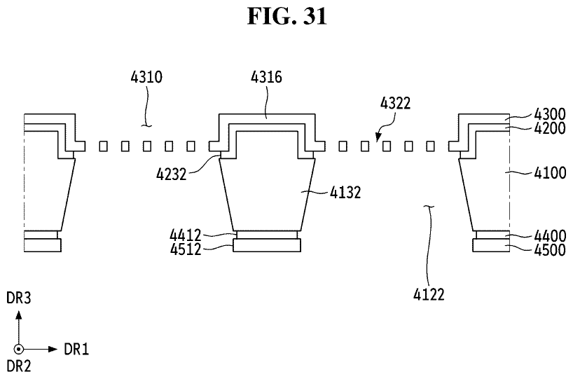

Referring to FIG. 31, in an embodiment of a method of manufacturing a deposition mask, the intermediate inorganic film 4200 may be partially removed to form the intermediate openings 4232 exposing the mask cell regions 4320. The intermediate openings 4232 may be formed by a wet etching process. In an embodiment, for example, the portions of the intermediate inorganic film 4200 exposed by the cell openings 4122 may be removed by a second wet etching process using a second etchant such as BOE or diluted HF, thereby connecting the pixel openings 4322 to the cell openings 4112 through the intermediate openings 4232.

In particular, the intermediate inorganic film 4200 may be isotropically etched by the second etchant, and thus the width 4232a of the intermediate openings 4232 may be greater than the first width 4122a of the cell openings 4122 as shown in FIG. 21. In addition, after the intermediate openings 4232 are formed, as illustrated in FIG. 21, portions 4234 of the intermediate inorganic film 4200 having a ring shape, for example, a quadrangular ring shape may remain on the bottom edge portions 4116 of the recesses 4110, that is, the stepped portions 4116 of the mask substrate 4100. That is, the ring-shaped inorganic patterns 4234 surrounding the intermediate openings 4232 may be formed on the stepped portions 4116 of the mask substrate 4100 by the second wet etching process, and the intermediate openings 4232 may be defined by the ring-shaped inorganic patterns 4234. In this case, the mask cell regions 4320 of the membrane 4300 may be supported by the ring-shaped portions 4234 of the intermediate inorganic film 4200 and the bottom edge portions 4116 of the recesses 4110. In this case, the ring-shaped portions 4234 of the intermediate inorganic film 4200 and the bottom edge portions 4116 of the recesses 4110 may function as support members supporting the mask cell regions 4320. Accordingly, the rigidity of the mask cell regions 4320 may be improved, and the warpage of the mask cell regions 4320 may be reduced.

According the embodiments of the present disclosure as described above, in a deposition process using the deposition mask 4000, the mask cell regions 4320 of the membrane 4300 may be positioned lower than the grid region 4330 of the membrane 4300, and thus, the mask cell regions 4320 of the membrane 4300 may be spaced apart from the backplane substrate 3000 while the deposition process is performed. As a result, the mask cell regions 4320 of the membrane 4300 may be prevented from coming into contact with the backplane substrate 3000, and thus damage to the mask cell regions 4320 of the membrane 4300 may be effectively prevented or substantially reduced. Additionally, damage to the mask cell regions 4320 may be reduced although foreign matters are present between the backplane substrate 3000 and the deposition mask 4000.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A deposition mask comprising:
a mask substrate; and
a membrane disposed on the mask substrate,
wherein an upper opening is defined in a front surface portion of the mask substrate and a cell opening is defined in a rear surface portion of the mask substrate and connected to the upper opening, and
the membrane comprises:
a mask cell region disposed in the upper opening and provided with a plurality of pixel openings defined therethrough; and
a grid region disposed on a front surface of the mask substrate.

2. The deposition mask of claim 1, further comprising an intermediate inorganic film disposed between the mask substrate and the membrane,
wherein the intermediate inorganic film is provided with an intermediate opening connecting the mask cell region and the cell opening to each other in a way such that the mask cell region is exposed through the cell opening.

3. The deposition mask of claim 2, wherein inner side surfaces of the mask substrate defining the cell opening are directly connected to inner side surfaces of the mask substrate defining the upper opening.

4. The deposition mask of claim 2, wherein the intermediate opening has a width equal to a width of the upper opening.

5. The deposition mask of claim 1, wherein the upper opening is a recessed opening connected to the cell opening.

6. The deposition mask of claim 5, further comprising an intermediate inorganic film disposed between the mask substrate and the membrane,
wherein the intermediate inorganic film is provided with an intermediate opening defined between the mask cell region and the cell opening in a way such that the pixel openings communicate with the cell opening.

7. The deposition mask of claim 6, wherein the intermediate opening has a width greater than a width of the cell opening.

8. The deposition mask of claim 6, wherein the cell opening has a first width adjacent to the front surface of the mask substrate and a second width adjacent to a rear surface of the mask substrate, and
the intermediate opening has a width greater than the first width of the cell opening.

9. The deposition mask of claim 6, wherein the mask substrate comprises a ring-shaped stepped portion surrounding the cell opening,
the upper opening is defined by the ring-shaped stepped portion,
the intermediate inorganic film comprises a ring-shaped inorganic pattern disposed on the ring-shaped stepped portion and surrounding the intermediate opening, and
the mask cell region is supported by the ring-shaped inorganic pattern and the ring-shaped stepped portion.

10. A method of manufacturing a deposition mask, the method comprising:
forming a recess in a front surface portion of a mask substrate;
forming a membrane on a front surface of the mask substrate and inner surfaces of the mask substrate defining the recess;
forming a plurality of pixel openings through a portion of the membrane formed on a bottom surface of the mask substrate defining the recess; and
forming a cell opening through the mask substrate to be connected to the pixel openings.

11. The method of claim 10, further comprising forming an intermediate inorganic film on the front surface of the mask substrate and the inner surfaces of the mask substrate defining the recess,
wherein the membrane is formed on the intermediate inorganic film, and
the pixel openings are formed in a way such that portions of the intermediate inorganic film formed on the bottom surface of the mask substrate defining the recess are removed.

12. The method of claim 11, further comprising forming an intermediate opening connecting the pixel openings and the cell opening by partially removing the intermediate inorganic film.

13. The method of claim 12, wherein the cell opening is formed in a way such that inner side surfaces of the mask substrate defining the recess are directly connected to inner side surfaces of the mask substrate defining the cell opening, and
the intermediate opening is formed to have a width equal to a width of the recess.

14. The method of claim 10, wherein the cell opening is formed in a way such that the bottom surface of the mask substrate defining the recess is partially removed.

15. The method of claim 14, further comprising forming an intermediate inorganic film on the front surface of the mask substrate and the inner surfaces of the mask substrate defining the recess,
wherein the membrane is formed on the intermediate inorganic film, and
a portion of the intermediate inorganic film formed on the bottom surface of the recess is partially exposed by the cell opening.

16. The method of claim 15, further comprising removing a portion of the intermediate inorganic film exposed by the cell opening to form an intermediate opening connecting the pixel openings and the cell opening to each other.

17. The method of claim 16, wherein the intermediate opening is formed to have a width less than a width of the recess.

18. The method of claim 16, wherein while the forming the cell opening, a ring-shaped stepped portion surrounding the cell opening is formed, and
while the forming the intermediate opening, a ring-shaped inorganic pattern surrounding the intermediate opening is formed on the ring-shaped stepped portion.

19. An electronic device comprising a display panel,
wherein the display panel comprises a backplane substrate and a plurality of light emitting layers formed on the backplane substrate using a deposition mask,
the deposition mask comprises a mask substrate and a membrane disposed on the mask substrate,
an upper opening is defined in a front surface portion of the mask substrate and a cell opening is defined in a rear surface portion of the mask substrate and connected to the upper opening, and
the membrane comprises:
a mask cell region disposed in the upper opening and provided with a plurality of pixel openings defined therethrough; and
a grid region disposed on a front surface of the mask substrate.

20. The electronic device of claim 19, further comprising at least one selected from a processor, a memory, and a power module.
